(19) United States
(12) Patent Application Publication
(10) Pub. No.: US 2025/0048612 A1
(43) Pub. Date: Feb. 6, 2025

(54) REDUCTION OF SIZE OF EDGE CELL REGION IN MEMORY DEVICES

(71) Applicant: Taiwan Semiconductor Manufacturing Company, Ltd., Hsin-Chu (TW)

(72) Inventors: Jui-Lin Chen, Taipei City (TW); Feng-Ming Chang, Hsinchu County (TW); Ping-Wei Wang, Hsin-Chu (TW); Yu-Bey Wu, Hsinchu City (TW); Chih-Ching Wang, Kinmen County (TW)

(21) Appl. No.: 18/404,467

(22) Filed: Jan. 4, 2024

Related U.S. Application Data
(60) Provisional application No. 63/517,531, filed on Aug. 3, 2023.

(51) Int. Cl. H10B 10/00; H01L 23/522; H01L 23/528

(52) U.S. Cl. CPC H10B 10/125; H01L 23/5226; H01L 23/5283

(57) ABSTRACT

An integrated circuit (IC) device has a memory region in which a plurality of memory cells is implemented. Each of the memory cells has a first dimension in a first horizontal direction. The IC device includes an edge region bordering the memory cell region in the first horizontal direction. The edge region has a second dimension in the first horizontal direction. The second dimension is less than or equal to about 4 times the first dimension. The IC device is formed by revising a first IC layout to generate a second IC layout. The second IC layout is generated by shrinking a dimension of the edge region in the first horizontal direction.

### PRIORITY DATA

This application claims priority to U.S. Provisional Patent Application Ser. No. 63/517,531, filed Aug. 3, 2023, entitled “NOVEL SPR EDGE CELL TAPLESS WITH FTV”, the entirety of which is incorporated herein by reference.

### BACKGROUND

The electronics industry has experienced an ever-increasing demand for smaller and faster electronic devices which are simultaneously able to support a greater number of increasingly complex and sophisticated functions. Accordingly, there is a continuing trend in the semiconductor industry to manufacture low-cost, high-performance, and low-power integrated circuits (ICs). Thus far, these goals have been achieved in large part by scaling down semiconductor IC dimensions (e.g., minimum feature size) and thereby improving production efficiency and lowering associated costs. However, such scaling has also introduced increased complexity to the semiconductor manufacturing process. Thus, the realization of continued advances in semiconductor ICs and devices calls for similar advances in semiconductor manufacturing processes and technology.

As integrated circuit devices get scaled down, it may be desirable to efficiently utilize the available areas on an IC chip. However, in many memory devices (e.g., Static Random Access Memory (SRAM)), the edge cells still take up more space than is necessary, which may be considered a waste of the valuable chip real estate. Therefore, while the IC layout designs for memory device designs are generally adequate for their intended purposes, they are not satisfactory in all aspects.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1 is a circuit schematic of an SRAM cell according to various aspects of the present disclosure.

FIG. 2 is a top view of a portion of a memory device that includes an SRAM region, an edge region, and a non-SRAM region according to various aspects of the present disclosure.

FIG. 3 is a cross-sectional side view of a portion of a memory device in which an example feedthrough via is implemented according to various aspects of the present disclosure.

FIGS. 4A-21A each illustrate a portion of an original IC layout according to various aspects of the present disclosure.

FIGS. 4B-21B each illustrate a portion of a revised IC layout according to various aspects of the present disclosure.

FIG. 4C illustrates a portion of a revised IC layout according to various aspects of the present disclosure.

FIG. 4D is a cross-sectional side view of a portion of a memory device in which a dielectric isolation structure is implemented according to various aspects of the present disclosure.

FIG. 15C is a cross-sectional side view of a portion of a memory device in which a dielectric isolation structure is implemented according to various aspects of the present disclosure.

FIG. 19C is a portion of a revised IC layout corresponding to an edge region 120B with metal routing components included according to various aspects of the present disclosure.

FIG. 22 is a block diagram of a manufacturing system according to various aspects of the present disclosure.

FIG. 23 is a flowchart illustrating a method of revising an IC layout design according to various aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed. Throughout the disclosure, like reference numerals denote like features and may indicate similar compositions or formation processes unless otherwise described. For that reason, features with the same reference numerals may only be described once for simplicity.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art. Still further, the present disclosure may repeat reference numerals and/or letters in the various examples. This repetition is for the purpose of simplicity and clarity and does not in itself dictate a relationship between the various embodiments and/or configurations discussed.

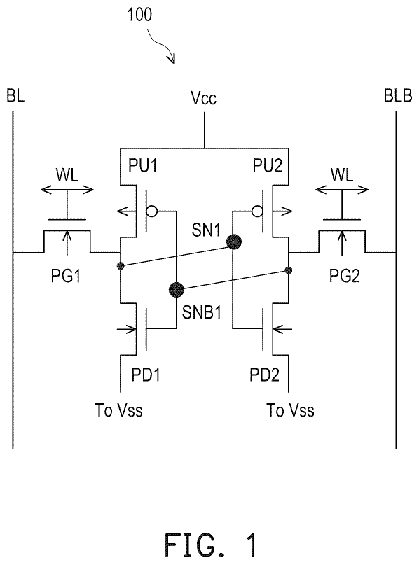

FIG. 1 illustrates an example type of memory device in which transistors such as planar transistors, FinFET transistors, or gate-all-around (GAA) transistors may be implemented. In that regard, FIG. 1 illustrates the circuit schematic of an example Static Random-Access Memory (SRAM) device, for example, as a single-port SRAM cell (e.g., 1-bit SRAM cell) 100. The single-port SRAM cell 100 includes pull-up transistors PU1, PU2; pull-down transistors PD1, PD2; and pass-gate transistors PG1, PG2. As show in the circuit diagram, transistors PU1 and PU2 are p-type transistors, and transistors PG1, PG2, PD1, and PD2 are n-type transistors. According to the various aspects of the present disclosure, the PG1, PG2, PD1, and PD2 transistors are implemented with thinner spacers than the PU1 and PU2 transistors. Since the SRAM cell 100 includes six transistors in the illustrated embodiment, it may also be referred to as a 6T SRAM cell. Regardless, transistors such as the FinFET or GAA transistors may be used to implement the PG1, PG2, PD1, PD2, PU1, and/or the PU2 transistors.

The drains of pull-up transistor PU1 and pull-down transistor PD1 are coupled together, and the drains of pull-up transistor PU2 and pull-down transistor PD2 are coupled together. Transistors PU1 and PD1 are cross-coupled with transistors PU2 and PD2 to form a first data latch. The gates of transistors PU2 and PD2 are coupled together and to the drains of transistors PU1 and PD1 to form a first storage node SN1, and the gates of transistors PU1 and PD1 are coupled together and to the drains of transistors PU2 and PD2 to form a complementary first storage node SNB1. Sources of the pull-up transistors PU1 and PU2 are coupled to power voltage Vcc (also referred to as Vdd), and the sources of the pull-down transistors PD1 and PD2 are coupled to a voltage Vss, which may be an electrical ground in some embodiments.

The first storage node SN1 of the first data latch is coupled to bit line BL through pass-gate transistor PG1, and the complementary first storage node SNB1 is coupled to complementary bit line BLB through pass-gate transistor PG2. The first storage node SN1 and the complementary first storage node SNB1 are complementary nodes that are often at opposite logic levels (logic high or logic low). Gates of pass-gate transistors PG1 and PG2 are coupled to a word line WL. SRAM devices such as the SRAM cell 100 may be implemented using “planar” transistor devices, with FinFET devices, and/or with GAA devices.

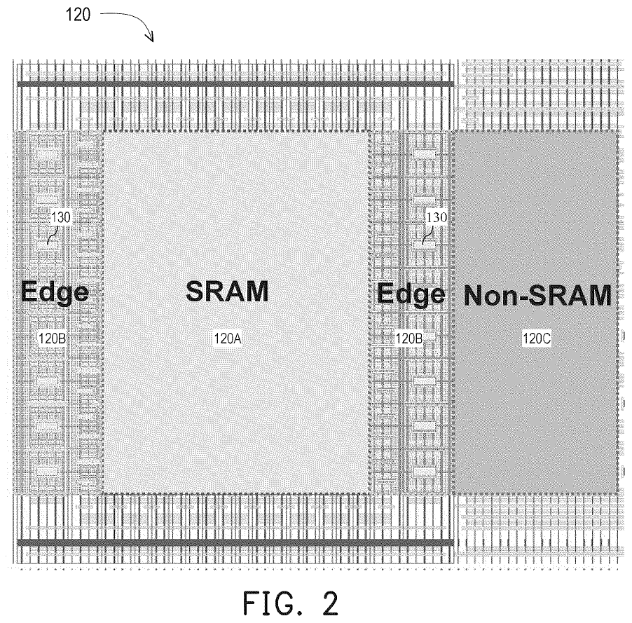

FIG. 2 is a diagrammatic fragmentary planar top view of a portion of a memory device 120. The memory device 120 may include an SRAM region 120A. The SRAM region 120A is the region of the memory device where a plurality of SRAM devices (e.g., the SRAM cell 100 of FIG. 1) are implemented. For example, the plurality of SRAM devices may be implemented as an SRAM array in the SRAM region 120A. The memory device 120 may also include an edge region 120B. The edge region 120B surrounds the SRAM region 120A but does not contain any SRAM cells therein. In some embodiments, the edge region 120B may contain feedthrough vias (FTVs) 130. In that regard, FTVs 130 are utilized to help establish electrical connections within the memory device 120.

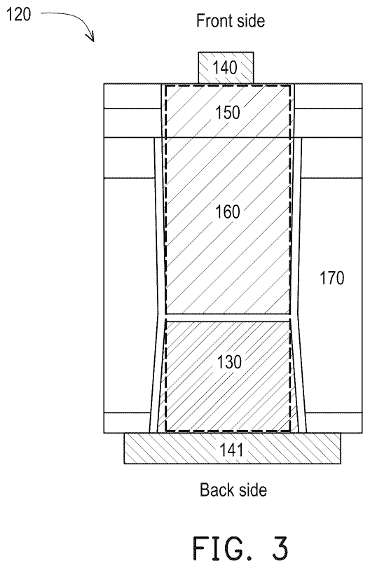

For example, FIG. 3 illustrates a diagrammatic fragmentary cross-sectional side view of a portion of the memory device 120 in which an example FTV 130 is implemented. In more detail, FIG. 3 has a front side and a back side. Metallization structures may be implemented in both the front side and the back side of the memory device 120 to provide electrical connectivity. For example, a metal layer 140 (e.g., as a metal-0 layer) may be formed over the front side of the memory device 120 to provide electrical connectivity to the components of the memory device 120 from the front side, and a metal layer 141 (e.g., as a back side metal-0 layer) may be formed over the back side of the memory device 120 to provide electrical connectivity to the components of the memory device 120 from the back side. The metal layer 140 and the metal layer 141 are electrically coupled together by a plurality of other conductive components, such as a conductive via 150, a conductive contact 160, as well as the FTV 130. As shown in FIG. 3, the conductive contact 160 extends vertically from the front side toward the back side, and the FTV extends vertically from the back side toward the front side. Collectively, the conductive contact 160 and the FTV 130 may substantially extend vertically through an interlayer dielectric 170, which may be made of an electrically insulative material, such as silicon oxide.

Referring back to FIG. 2, the memory device 120 further includes a non-SRAM region 120C that is separated from the SRAM region 120A by the edge region 120B. The non-SRAM region 120C may also be referred to as a periphery region or a logic region. Rather than including the SRAM cells themselves, the non-SRAM region 120C may include components such as input/output devices, logic devices, and/or drivers (e.g., word-line drivers) for controlling/operating the SRAM cells of the SRAM region 120A.

According to various aspects of the present disclosure, the edge region 120B may be unnecessarily big. It would be advantageous to shrink the size of the edge region 120B, so that the overall size of the memory device 120 may be reduced accordingly, or that the size of the SRAM region 120A may be enlarged to pack more SRAM cells inside the SRAM region 120A. As will be discussed in detail below, the size of the edge region 120B may be reduced by various IC layout reconfigurations and/or implementations of additional IC components.

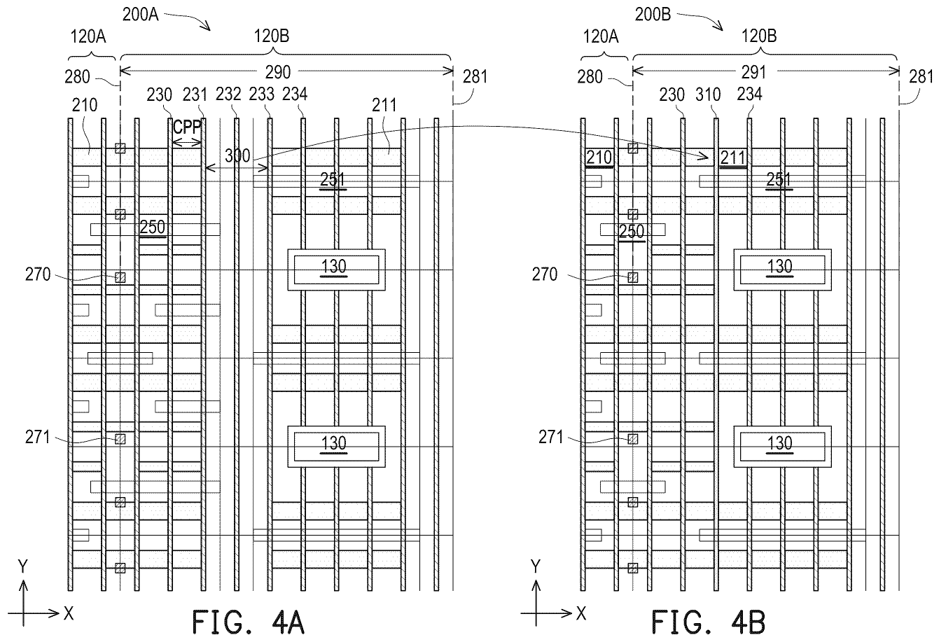

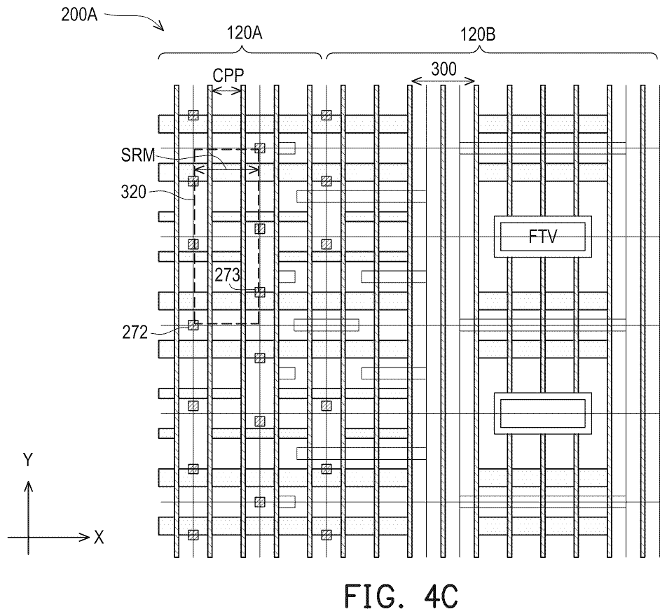

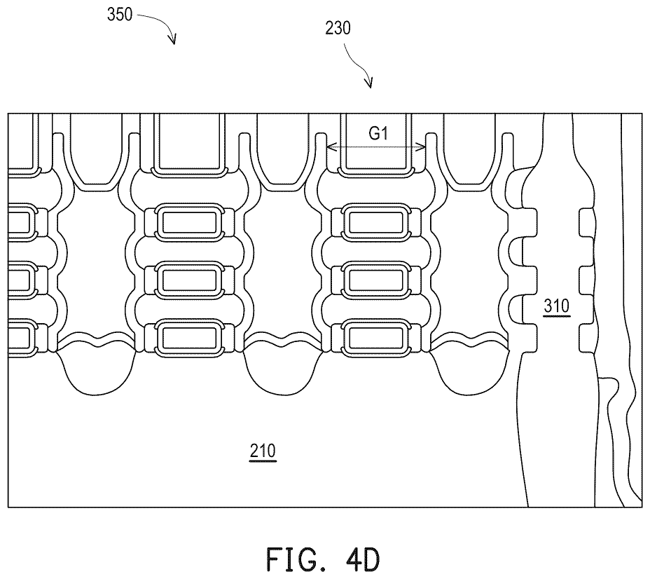

For example, FIG. 4A illustrates an original IC layout 200A of a portion of the memory device 120 before the edge region 120B is shrunk, and FIG. 4B illustrates a revised IC layout 200B of the portion of the memory device 120 after the edge region 120B has been shrunk. The original IC layout 200A and the revised IC layout 200B each include an X-direction and a Y-direction that is perpendicular to the X-direction. The X-direction and the Y-direction are horizontal directions that collectively defined a horizontal plane, which means that FIGS. 4A-4B are planar top views.

In some embodiments, the original IC layout 200A may be generated by an IC design house, which may not have a fabrication facility. The original IC layout 200A may be sent to an IC foundry. The IC foundry may then generate the revised IC layout 200B based on the original IC layout 200A, for example, by shrinking a size of the edge region 120B in the X-direction. In some embodiments, the original IC layout 200A and the revised IC layout 200B may each include a computer file in a Graphic Design System (GDS) format. For example, the GDS file may be a binary file that contains information representing planar geometric shapes, text labels, and other information about the IC layout in a hierarchical form.

As is shown in FIG. 4A, the edge region 120B borders the SRAM region 120A (only a small portion thereof is shown herein) in the X-direction. The SRAM region 120A and the edge region 120B each include a plurality of active regions (also referred to as OD), for example, active regions 210 and 211. In some embodiments, the active regions 210 and 211 may include the fin structures of FinFET transistors, where the fin structures rise vertically out of a substrate. Source/drain components and/or a channel component of a transistor may be formed in or on the active regions such as the active regions 210 and 211. The active regions 210 and 211 each extend in the X-direction. The active region 210 is located both in the SRAM region 120A and the edge region 120B. In other words, a portion of the active region 210 is in the SRAM region 120A, and another portion of the active region 210 is in the edge region 120B. In comparison, the active region 211 is located in the edge region 120B, but not in the SRAM region 120A.

The SRAM region 120A and the edge region 120B also include a plurality of gate structures, such as gate structures 230, 231, 232, 233, and 234. The gate structures 230-234 each extend in the Y-direction that is perpendicular to the X-direction. Although it may not be readily apparent in the planar top view of FIG. 4A, the gate structures 230-234 may each partially wrap around a plurality of the fin structures, such as the fin structures corresponding to the active regions 210 or 211. In some embodiment, the gate structures 230-234 may include high-k metal gate (HKMG) structures that are formed by a gate replacement process. In such a gate replacement process, dummy gate structures (e.g., polysilicon dummy gate structures) may be formed, and following the formation of source/drain components, the dummy gate structures are removed and replaced by the HKMG structures. The HKMG structures may each include a high-k gate dielectric and a metal gate electrode. Example materials of the high-k gate dielectric include hafnium oxide, zirconium oxide, aluminum oxide, hafnium dioxide-alumina alloy, hafnium silicon oxide, hafnium silicon oxynitride, hafnium tantalum oxide, hafnium titanium oxide, hafnium zirconium oxide, or another suitable dielectric material having a dielectric constant greater than about 3.9. The metal gate electrode may include one or more work function metal layers and one or more fill metal layers. The work function metal layers may be configured to tune a work function of the respective transistor. Example materials for the work function metal layers may include titanium nitride (TiN), Titanium aluminide (TiAl), tantalum nitride (TaN), titanium carbide (TiC), tantalum carbide (TaC), tungsten carbide (WC), aluminum titanium nitride (TiAlN), zirconium aluminide (ZrAl), tungsten aluminide (WAl), tantalum aluminide (TaAl), hafnium aluminide (HfAl), or combinations thereof. The fill metal layer may serve as a main conductive portion of the gate electrode layer.

The SRAM region 120A and the edge region 120B may further include a plurality of electrical isolation structures that intersect with the gate structures in the top view. For example, an electrical isolation structure 250 is located in both the SRAM region 120A and the edge region 120B, where the electrical isolation structure 250 intersects with the gate structures 230 and 231. Meanwhile, an electrical isolation structure 251 is located in the edge region 120B, where the electrical isolation structure 251 intersects with the gate structures 233 and 234. The electrical isolation structures 250 and 251 each extend in the X-direction. In some embodiments, the electrical isolation structures 250 and 251 may be formed by etching openings that extend vertically through at least some of the gate structures, and subsequently filling the etched openings with one or more dielectric materials (e.g., silicon oxide, silicon nitride, silicon carbide, silicon oxynitride, etc.). The dielectric materials filling the openings provide electrical isolation, which allows the electrical isolation structures 250 and 251 to cut each of the gate structures (e.g., the gate structures 230-231 and 233-234) into two segments that are electrically isolated from each other.

The SRAM region 120A further includes a plurality of conductive vias, such as conductive vias 270 and 271. In some embodiments, the conductive vias 270-271 may be Vss vias of the SRAM cell. The conductive vias 270-271 (along with the other unlabeled conductive vias) are aligned in the Y-direction, and these conductive vias may collectively define a boundary of the SRAM region 120A. In other words, an imaginary line 280 crossing over the vertically aligned conductive vias (such as the conductive vias 270-271) may constitute a border between the SRAM region 120A and the edge region 120B. As such, an original size 290 (e.g., a dimension measured in the X-direction) of the edge region 120B may span from the imaginary line 280 to another imaginary line 281 that corresponds to another border of the edge region 120B (e.g., a border opposite the border defined by the imaginary line 280). In other words, the imaginary lines 280 and 281 represent opposing borders of the edge region 120B, and they may be referred interchangeably as the borders 280 and 281 of the edge region hereinafter. The distance between these two imaginary lines 280-281 in FIG. 4A corresponds to the original size 290 (e.g., as a dimension in the X-direction) of the edge region 120B according to the original IC layout 200A.

According to various aspects of the present disclosure, the original size 290 may be unduly large and should be shrunk. In that regard, one contribution to the original size 290 is the existence of a dummy space 300 in the edge region 120B in the original IC layout 200A. In more detail, the original IC layout 200A includes the dummy space 300 between the gate structure 231 and the gate structure 233 in the edge region 120B, where the gate structure 232 spans the dummy space 300 in the Y-direction. Due to the existence of such a dummy space 300, the active regions in the SRAM region 120A are not directly abutted to the active regions in the edge region 120B. In other words, the dummy space 300 keeps the active region 210 electrically and physically separated from the active region 211.

One reason for the implementation of such a dummy space 300 is to alleviate the concerns of electrical leakage between the FTVs 130 in the edge region 120B and the SRAM cells in the SRAM region 120A. The present disclosure addresses such electrical leakage concerns by the implementation of a dielectric isolation structure 310 in the revised IC layout 200B. For example, referring to FIG. 4B, the dielectric isolation structure 310 extends in the Y-direction and effectively replaces the dummy space 300 in the original IC layout 200A of FIG. 4A. In this manner, it may be said that the active region 210 and the active region 211 are both directly abutted to the dielectric isolation structure 310 (but on opposite sides of the dielectric isolation structure 310) in the revised IC layout 200B of FIG. 4B. Since the dielectric isolation structure 310 is electrically insulating, it can reduce potential leakage issues between the FTVs 130 in the edge region 120B and the SRAM cells in the SRAM region 120A.

The elimination of the dummy space 300 (including the gate structures 231-233) translates into a reduction of the original size 290 of the edge region 120B in the original IC layout 200A into a reduced size 291 of the edge region 120B in the revised IC layout 200B. In other words, the reduced size 291 is less than the original size 290 of the edge region 120B. In the illustrated embodiment, the original size 290 may be approximately equal to 10 times of the gate pitch (also referred to as CPP and labeled in FIGS. 4A-4B as such), where each CPP is a distance between an adjacently located pair of gate structures (e.g., a distance between the gate structure 230 and 231). Of the 10 CPPs that correspond to the original size 290 of the edge region 120B, two CPPs are from the dummy space 300. In the revised IC layout 200B, the dummy space 300 is removed, which frees up two CPPs. As such, the reduced size 291 of the edge region 120B is approximately equal to 8 CPPs, rather than 10 CPPs.

Note that the original size 290 and/or the reduced size 291 may also be expressed in terms of a width of an SRAM cell. In that regard, referring now to FIG. 4C, another portion of the original IC layout 200A is illustrated. The original IC layout 200A shown in FIG. 4C illustrates an outline or a contour 320 of an SRAM cell. The contour 320 may resemble a rectangle, and a width of the SRAM cell is measured by a horizontal distance (measured in the X-direction) between a Vss via 272 and Vss via 273 that is located adjacent to the Vss via 272 in the X-direction. The width of the SRAM cell is labeled as SRM in FIG. 4C, and the SRM is approximately equal to twice the CPP (i.e., the gate pitch). In other words, SRM=2×CPP. Therefore, in terms of the SRAM cell width SRM, the original size 290 of the edge region 120B of the original IC layout 200A is 5 times the SRM, and the reduced size 291 of the edge region 120B of the revised IC layout 200B is 4 times the SRM.

Referring now to FIG. 4D, a diagrammatic cross-sectional side view of a portion of an IC device 350 is illustrated. The IC device 350 corresponds to a device fabricated according to the revised IC layout 200B of FIG. 4B discussed above. For example, the IC device 350 includes an active region that extends in the X-direction horizontally, and a plurality of gate structures such as the gate structure 230 that protrude vertically in the Z-direction from the active region 210. In the embodiment shown in FIG. 4D, the IC device 350 is a GAA device, but other devices, such as FinFET devices or planar devices, may also be implemented according to the revised IC layout 200B. In any case, FIG. 4D also illustrates the dielectric isolation structure 310. The dielectric isolation structure 310 may be formed by etching an opening in a portion of the IC device 350 (e.g., in a dummy gate structure or the HKMG gate structure), and subsequently filling the opening with a dielectric material, such as with silicon nitride in some embodiments or with other suitable dielectric materials in other embodiments. The resulting dielectric isolation structure 310 may extend into the active region 210 and may have an upper surface that is substantially co-planar with the gate structures 230.

One benefit provided by the dielectric isolation structure 310 is that it mitigates the risk of an epi mushroom. In that regard, an epi mushroom (e.g., an undesirable expansion or spillover of epitaxial source/drain on a side of a gate structure) may result during the fabrication of the IC device 350, which may be partially attributed to overlay issues. Such an epi mushroom issue could lead to undesirable electrical shorting. Here, the implementation of the dielectric isolation structure 310 can effectively reduce the risk of epi mushroom.

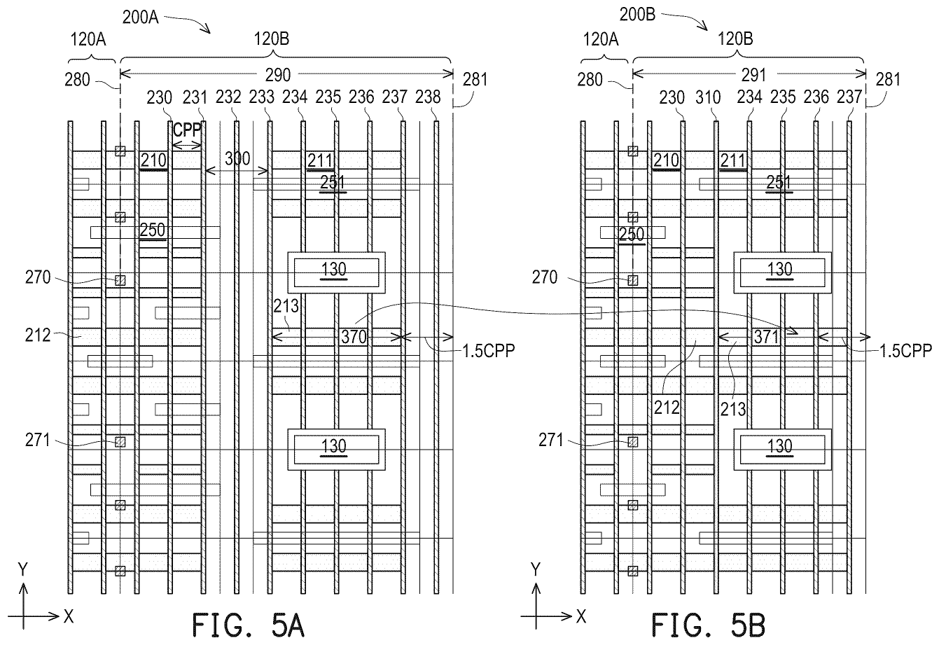

FIGS. 4A-4B discussed above correspond to a first embodiment of shrinking the edge region 120B of a memory device. FIGS. 5A-5B correspond to a second embodiment of shrinking the edge region 120B of a memory device. For reasons of consistency and clarity, similar components appearing in FIGS. 4A-4B will be labeled the same in FIGS. 5A-5B.

In more detail, FIG. 5A illustrates an original IC layout 200A of a portion of the memory device 120 before the edge region 120B is shrunk, and FIG. 5B illustrates a revised IC layout 200B of the portion of the memory device 120 after the edge region 120B has been shrunk. FIG. 5A appears substantially similar to FIG. 4A, though with the labeling of additional gate structures 235-238, as well as the labeling of additional active regions 212 and 213. Again, whereas the active regions 212 and 213 are separated by the dummy space 300 in the original IC layout 200A, the active regions 212 and 213 are directly abutted to opposite sides of the dielectric isolation structure 310 in the revised IC layout 200B, due to the elimination of the dummy space 300.

According to the second embodiment, the size of the active regions in the edge region 120B (e.g., the active regions 211 and 213) are shrunk in the X-direction to achieve further reduction of the size of the edge region 120B. In more detail, an IC layout design rule may specify that a minimum spacing of 1.5 CPP should exist between a border of the edge region 120B (e.g., the border corresponding to the imaginary line 281) and the nearest edge of the nearest active region (e.g., the active region 211 or 213). However, there is no specific requirement on the size of the active region 211/213 in the X-direction in the edge region 120B. Taking advantage of these design rules (or the lack thereof), the second embodiment of the present disclosure generates the revised IC layout 200B also by shrinking the active regions 211 and 213 in the X-direction. For example, whereas the active region 213 (or 211) may have a horizontal dimension 370 (measured in the X-direction) in the original IC layout 200A of FIG. 5A, the active region 213 (or 211) may have a horizontal dimension 371 (also measured in the X-direction) in the revised IC layout 200B of FIG. 5B, where the horizontal dimension 371 is less than the horizontal dimension 370.

In some embodiments, the horizontal dimension 370 is approximately equal to 4 CPP, as the active region 211/213 in the original IC layout 200A spans from the gate structure 233 to the gate structure 237. In comparison, the horizontal dimension 371 is approximately equal to 3 CPP, as the active region 211/213 in the revised IC layout 200B spans from the dielectric isolation structure 310 to the gate structure 236. As such, the reduced size 291 of the edge region 120B now has a dimension of approximately 7 CPP in the second embodiment of FIG. 5B, which is 1 CPP less than the first embodiment of FIG. 4B. Again, when expressed in terms of the SRAM width SRM, the reduced size 291 of the edge region 120B is approximately equal to 3.5 SRM in the second embodiment of FIG. 5B, compared to 4 SRM in the first embodiment of FIG. 4B. Note that the edge of the active region 211/213 is still spaced apart from the border 281 of the edge region 120B by 1.5 CPP in the revised IC layout 200B, which means that the revised IC layout 200B still satisfies the IC layout design rules.

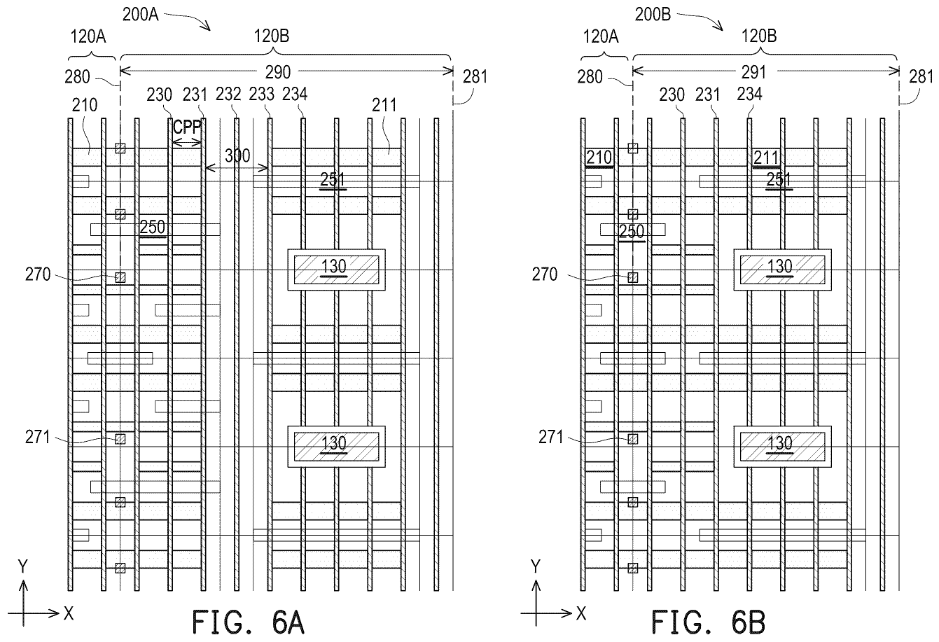

Referring now to FIGS. 6A-6B, a third embodiment of shrinking the edge region 120B of a memory device is illustrated. For reasons of consistency and clarity, similar components appearing in the figures discussed above will be labeled the same in FIGS. 6A-6B. In more detail, FIG. 6A illustrates an original IC layout 200A of a portion of the memory device 120 before the edge region 120B is shrunk, and FIG. 6B illustrates a revised IC layout 200B of the portion of the memory device 120 after the edge region 120B has been shrunk.

Similar to the first embodiment, the third embodiment corresponding to FIG. 6B also removes the dummy space 300, thereby achieving a reduction of 2 CPP (or 1 SRM) in terms of the size reduction for the reduced size 291 of the edge region 120B of the revised IC layout 200B, compared to the original size 290 of the edge region 120B of the original IC layout 200A. In other words, the reduced size 291 of the edge region 120B is approximately equal to 8 CPP or 4 SRM, as was the case in the first embodiment. However, whereas the first embodiment of FIG. 4B implements the dielectric isolation structure 310, the third embodiment of FIG. 6B need not implement such a dielectric isolation structure 310. Instead, one of the gate structures spanning the dummy space 300 (e.g., the gate structure 231) is kept in the revised IC layout 200B. In other words, the location of the gate structure 231 in the third embodiment of FIG. 6B may substantially coincide with the location of the dielectric isolation structure 310 in the revised IC layout 200B in the second embodiment of FIG. 5B discussed above. The active region 210 and the active region 211 directly abut one another due to the elimination of the dummy space 300. In the top view of FIG. 6B, the active regions 210-211 are located on opposite sides of the gate structure 231 (though it is understood that the gate structure 231 would partially wrap around the active regions 210-211 vertically). The third embodiment of FIG. 6B may be used in situations when the epi mushroom concerns are not significant enough to warrant the implementation of the dielectric isolation structure 310, which also helps to simply fabrication processes.

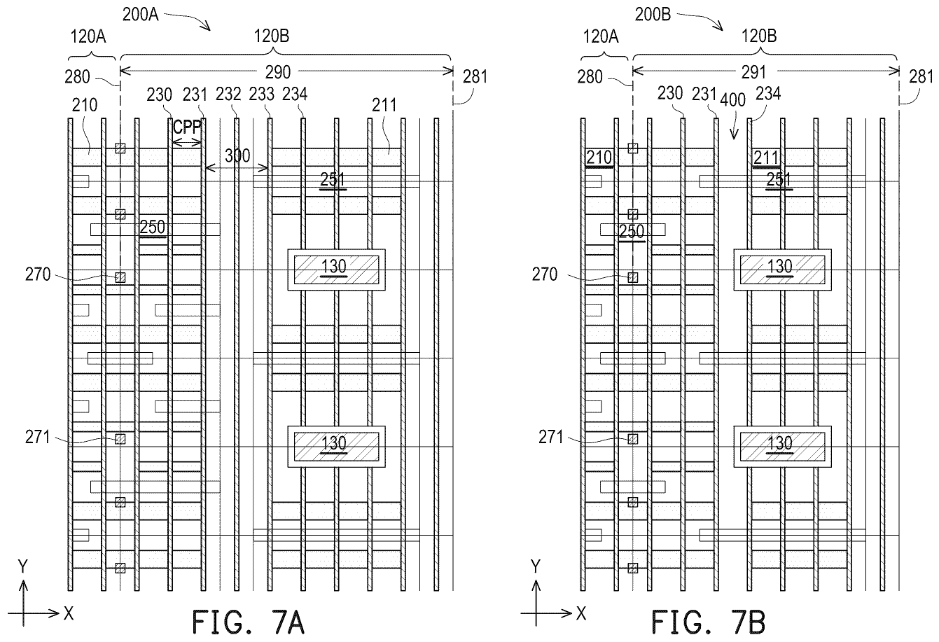

Referring now to FIGS. 7A-7B, a fourth embodiment of shrinking the edge region 120B of a memory device is illustrated. For reasons of consistency and clarity, similar components appearing in the figures discussed above will be labeled the same in FIGS. 7A-7B. In more detail, FIG. 7A illustrates an original IC layout 200A of a portion of the memory device 120 before the edge region 120B is shrunk, and FIG. 7B illustrates a revised IC layout 200B of the portion of the memory device 120 after the edge region 120B has been shrunk.

Similar to the third embodiment, the fourth embodiment corresponding to FIG. 7B also removes the dummy space 300 and implements the gate structure 231 (rather than the dielectric isolation structure 310) in place of the removed dummy space 300. However, whereas the third embodiment of FIG. 6B has continuous active regions (e.g., the active region 210 is continuously connected to the active region 211) spanning both the SRAM region 120A and the edge region 120B, the fourth embodiment of FIG. 7B breaks up the active regions. For example, an active-region-free zone 400 is implemented to separate the active region 210 from the active region 211. This may be done through lithography when the active regions are first defined. As a result, various active regions (such as the active region 210) may stop at, but does not extend past, the gate structure 231. In addition, no active region is abutting the other side of the gate structure 231, as the gate structure 231 is abutted to the active-region-free zone 400.

The breaking up of the active regions helps to prevent or reduce potential leakage between the FTVs 130 and the SRAM cells of the SRAM region 120A. In any case, the fourth embodiment of FIG. 7B still achieves the reduction of 2 CPP (or 1 SRM) for the reduced size 291 of the edge region 120B of the revised IC layout 200B, compared to the original size 290 of the edge region 120B of the original IC layout 200A. In other words, the reduced size 291 of the edge region 120B is approximately equal to 8 CPP or 4 SRM, as was the case in the first or third embodiments.

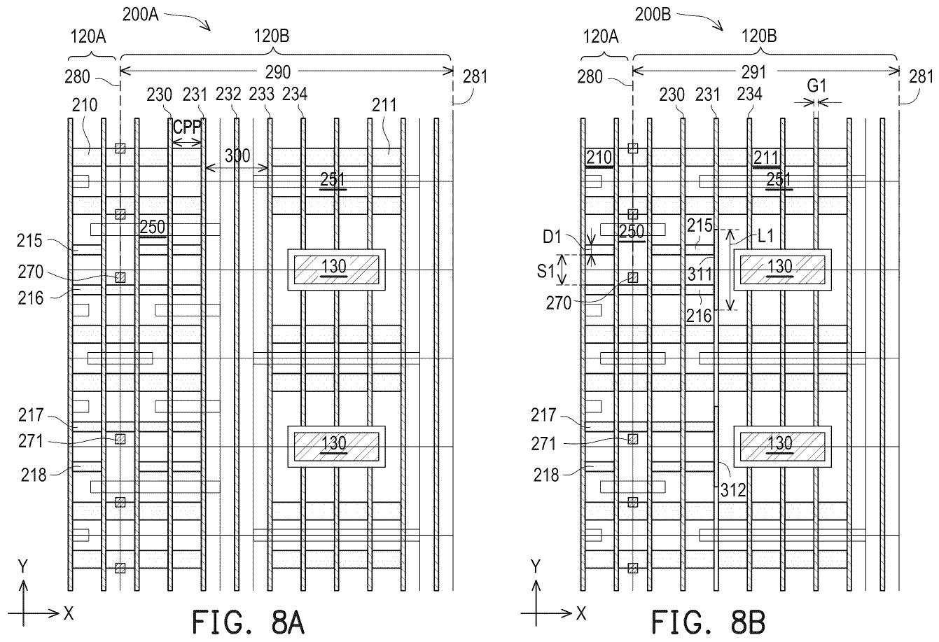

Referring now to FIGS. 8A-8B, a fifth embodiment of shrinking the edge region 120B of a memory device is illustrated. For reasons of consistency and clarity, similar components appearing in the figures discussed above will be labeled the same in FIGS. 8A-8B. In more detail, FIG. 8A illustrates an original IC layout 200A of a portion of the memory device 120 before the edge region 120B is shrunk, and FIG. 8B illustrates a revised IC layout 200B of the portion of the memory device 120 after the edge region 120B has been shrunk.

Similar to the first embodiment, the fifth embodiment corresponding to FIG. 8B also removes the dummy space 300. However, whereas the first embodiment implements a continuous dielectric isolation structure 310 that spans throughout the edge region 120B in the Y-direction, the fifth embodiment of FIG. 8B implements a plurality of discrete dielectric isolation structures, such as a dielectric isolation structure 311 and a dielectric isolation structure 312, in different regions of the edge region 120B. This is because the purpose of the dielectric isolation structure is to prevent or mitigate the epi mushroom issues, which occur at end portions of the active regions that are near the FTVs 130. In FIG. 8B, the active regions having potential epi mushroom issues are the active regions 215, 216, 217, and 218, whereas the other active regions extend continuously in the X-direction, and their line-end portions are not near the FTVs 130. As such, the dielectric isolation structures 311 and 312 just need to be deployed at the line-end portions of these active regions 215-218, but not necessarily elsewhere. Thus, the dielectric isolation structure 311 is implemented between the active regions 215-216 (directly abutting the active regions 215-216) and the FTV 130, and the dielectric isolation structure 312 is implemented between the active regions 217-218 (directly abutting the active regions 217-218) and the FTV 130. The dielectric isolation structure 311 can effectively prevent or mitigate the potential epi mushroom issues associated with the active regions 215-216, and the dielectric isolation structure 312 can effectively prevent or mitigate the potential epi mushroom issues associated with the active regions 217-218.

To ensure that the dielectric isolation structure 311 or 312 is sufficiently long (in the Y-direction) to prevent or mitigate the epi mushroom issue, the present disclosure configures the dielectric isolation structure 311 and the dielectric isolation structure 312 to each have a length L1 in the Y-direction. In some embodiments, the length L1 is greater than or equal to a sum of: two times a dimension of one of the active regions in the Y-direction and two times a spacing in the Y-direction between adjacently located active regions. In other words, L1>=2×D1+2×S1, where D1 represents the dimension of one of the active regions (e.g., the active region 215), and S1 represents the spacing in the Y-direction between the adjacently located active regions (e.g., spacing between the active regions 215 and 216). When L1 is configured as such, it will be able to sufficiently prevent or mitigate the potential epi mushroom issues discussed above. In addition, in order to optimize the dimensions herein, the present disclosure configures various ratios involving L1, D1, S1, and G1, where G1 represents a channel length (in the X-direction) of one of the gate structures. Note that G1 is also shown in FIG. 4D to provide further clarity. In some embodiments, 0.5<D1/G1<10, 1<S1/G1<10, and 1<L1/G1<50. In any case, the fifth embodiment of FIG. 8B also achieves 8 CPP or 4 SRM for the reduced size 291 of the edge region 120B in the revised IC layout 200B.

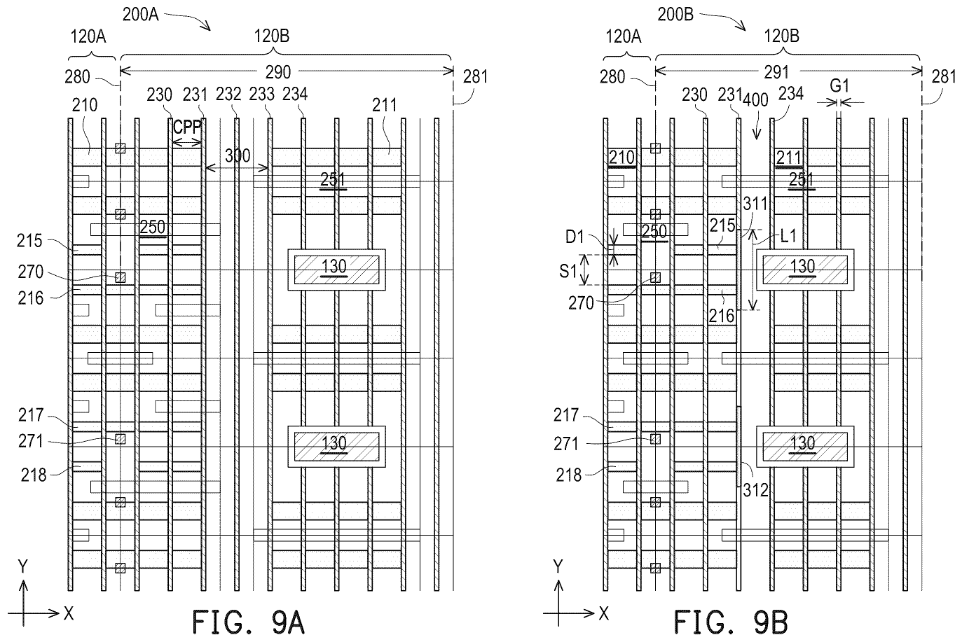

Referring now to FIGS. 9A-9B, a sixth embodiment of shrinking the edge region 120B of a memory device is illustrated. For reasons of consistency and clarity, similar components appearing in the figures discussed above will be labeled the same in FIGS. 9A-9B. In more detail, FIG. 9A illustrates an original IC layout 200A of a portion of the memory device 120 before the edge region 120B is shrunk, and FIG. 9B illustrates a revised IC layout 200B of the portion of the memory device 120 after the edge region 120B has been shrunk.

Similar to the fifth embodiment discussed above with reference to FIG. 8B, the sixth embodiment corresponding to FIG. 9B also removes the dummy space 300 and implements a plurality of discrete dielectric isolation structures 311 and 312 to prevent or mitigate epi mushrooms. However, whereas the fifth embodiment of FIG. 8B still includes some continuous active regions (e.g., where active regions 210 and 211 are directly abutted with respect to each other), the sixth embodiment of FIG. 9B breaks up the active regions. For example, the active-region-free zone 400 is implemented to separate the active region 210 from the active region 211. This may be done through lithography when the active regions are first defined. As a result, various active regions (such as the active region 210) may stop at, but does not extend past, the gate structure 231 or the dielectric isolation structures 311-312. As such, the sixth embodiment may be viewed as a combination of the fourth embodiment of FIG. 7B (having the active-region-free zone 400) and the fifth embodiment of FIG. 8B (having the plurality of discrete dielectric isolation structures 311-312). In any case, the sixth embodiment of FIG. 9B still achieves the reduction of 2 CPP (or 1 SRM) for the reduced size 291 of the edge region 120B of the revised IC layout 200B, compared to the original size 290 of the edge region 120B of the original IC layout 200A. In other words, the reduced size 291 of the edge region 120B is approximately equal to 8 CPP or 4 SRM, as was the case in the fourth or fifth embodiments discussed above.

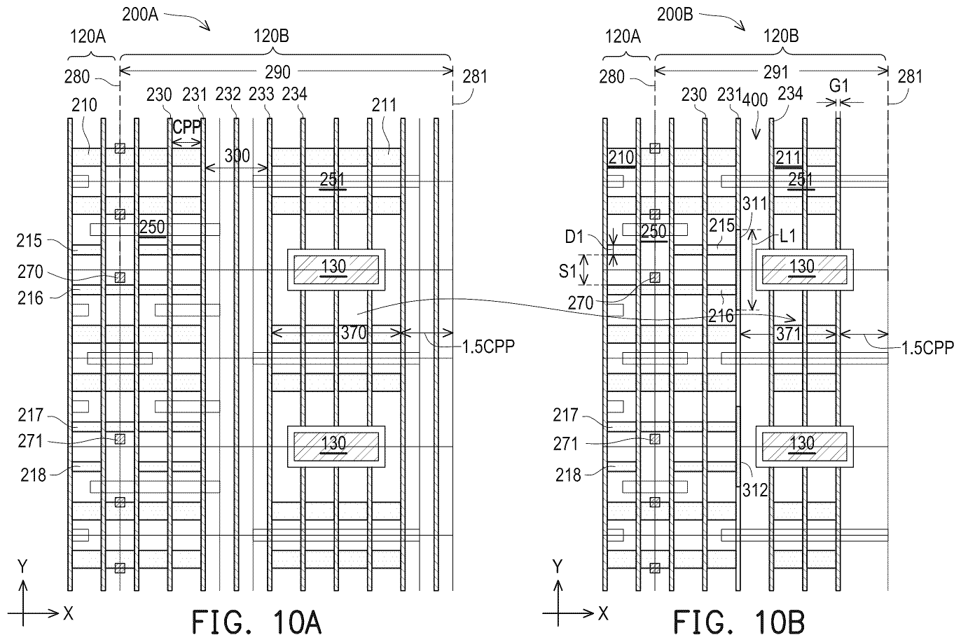

Referring now to FIGS. 10A-10B, a seventh embodiment of shrinking the edge region 120B of a memory device is illustrated. For reasons of consistency and clarity, similar components appearing in the figures discussed above will be labeled the same in FIGS. 10A-10B. In more detail, FIG. 10A illustrates an original IC layout 200A of a portion of the memory device 120 before the edge region 120B is shrunk, and FIG. 10B illustrates a revised IC layout 200B of the portion of the memory device 120 after the edge region 120B has been shrunk.

Similar to the sixth embodiment discussed above with reference to FIG. 9B, the seventh embodiment corresponding to FIG. 10B also removes the dummy space 300 and implements a plurality of discrete dielectric isolation structures 311 and 312 to prevent or mitigate epi mushrooms. The seventh embodiment of FIG. 10B also breaks up the active regions by implementing an active-region-free zone 400 to separate the active region 210 from the active region 211. However, whereas the sixth embodiment of FIG. 9B achieves a size reduction of 2 CPP (or 1 SRM) for the edge region 120B, the seventh embodiment of FIG. 10B achieves a size reduction of 3 CPP (or 1.5 SRM) for the edge region 120B. This is done by shrinking the active region 211 (and other similar active regions in the edge region 120B) in the X-direction. For example, whereas the active region 211 may have a horizontal dimension 370 (measured in the X-direction) in the original IC layout 200A of FIG. 10A, the active region 211 is resized to have a horizontal dimension 371 (also measured in the X-direction) in the revised IC layout 200B of FIG. 10B, where the horizontal dimension 371 is less than the horizontal dimension 370.

In some embodiments, the horizontal dimension 370 is approximately equal to 4 CPP, but the horizontal dimension 371 is approximately equal to 3 CPP. As such, the reduced size 291 of the edge region 120B now has a dimension of approximately 7 CPP in the seventh embodiment of FIG. 10B, which is 1 CPP less than the sixth embodiment of FIG. 9B. When expressed in terms of the SRAM width SRM, the reduced size 291 of the edge region 120B is approximately equal to 3.5 SRM in the seventh embodiment of FIG. 10B, compared to 4 SRM in the sixth embodiment of FIG. 9B. The edge of the active region 211 is still spaced apart from the border 281 of the edge region 120B by 1.5 CPP in the revised IC layout 200B, which means that the revised IC layout 200B still satisfies the IC layout design rules.

Note that the shrinking of the active regions (such as the active region 211) in the edge region 120B according to the seventh embodiment of FIG. 10B is substantially similar to that of the second embodiment discussed above with reference to FIG. 5B. As such, the seventh embodiment herein may be viewed as a combination of the sixth embodiment of FIG. 9B and the second embodiment of FIG. 5B.

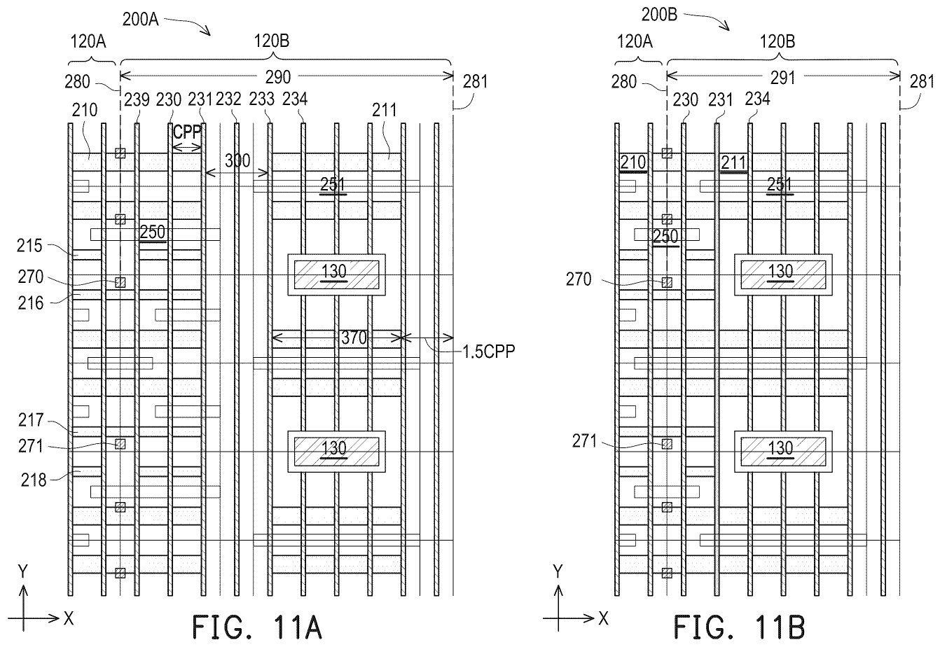

Referring now to FIGS. 11A-11B, an eighth embodiment of shrinking the edge region 120B of a memory device is illustrated. For reasons of consistency and clarity, similar components appearing in the figures discussed above will be labeled the same in FIGS. 11A-11B. In more detail, FIG. 11A illustrates an original IC layout 200A of a portion of the memory device 120 before the edge region 120B is shrunk, and FIG. 11B illustrates a revised IC layout 200B of the portion of the memory device 120 after the edge region 120B has been shrunk.

Similar to some of the embodiments discussed above, the eighth embodiment of FIG. 11B also eliminates the dummy space 300 of the original IC layout 200A and implements a dielectric isolation structure 231 in the edge region 120B of the revised IC layout 200B instead. However, unlike the previous embodiments discussed above, the eighth embodiment of FIG. 11B also shrinks the portion of the edge region 120B disposed to the “left” of the dummy space 300 as well. In that regard, the original IC layout 200A includes a plurality of dummy active regions, such as the active regions 215 and 218 shown in FIG. 11A. These dummy active regions 215 and 218 do not serve as a part of a transistor, and as such, they may be eliminated in the revised IC layout 200B. For example, the removal of the dummy active regions 215 and 218 may be configured during the lithography process used to define the active regions, where a mask pattern may be utilized to block the definition of the active regions that would have been the dummy active regions 215 and 218. In other words, the mask patterns are configured in lithography in a manner such that the dummy active regions 215 and 218 would not have been defined in the first place, which prevents their implementation as a part of the revised IC layout 200B.

Note that the removal of the dummy active regions 215 and 218 in the revised IC layout 200B also allows the removal of the gate structures 239 in the original IC layout 200A. For example, whereas the original IC layout 200A included three gate structures 239, 230, and 231 to the “left” of the dummy space 300, the revised IC layout 200B now just has one gate structure 230 located to the “left” of the dielectric isolation structure 231. In addition, some of the active regions, such as the active regions 210, 216, and 217, are resized to have a smaller dimension in the X-direction in the revised IC layout 200B. The size reduction may apply to the electrical isolation structure 250 and other similar electrical isolation structures as well. As a result of all of the above, the edge region 120B of the revised IC layout can achieve a reduced size 291 of approximately 7 CPP (or 3.5 SRM), which is a reduction of 3 CPP (or 1.5 SRM) compared to the original IC layout 200A.

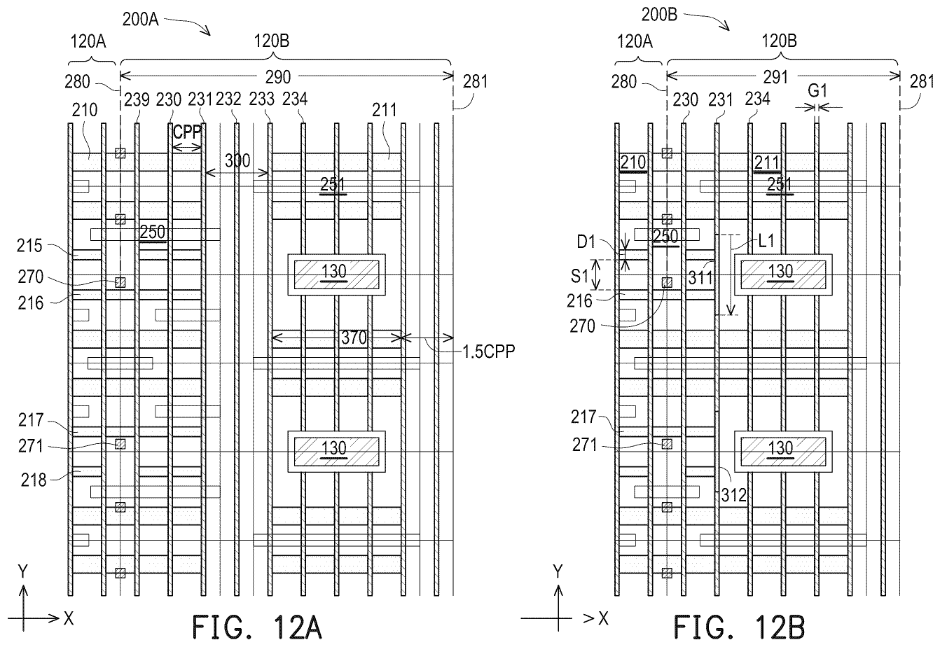

Referring now to FIGS. 12A-12B, a ninth embodiment of shrinking the edge region 120B of a memory device is illustrated. For reasons of consistency and clarity, similar components appearing in the figures discussed above will be labeled the same in FIGS. 12A-12B. In more detail, FIG. 12A illustrates an original IC layout 200A of a portion of the memory device 120 before the edge region 120B is shrunk, and FIG. 12B illustrates a revised IC layout 200B of the portion of the memory device 120 after the edge region 120B has been shrunk.

Similar to the eighth embodiment of FIG. 11B, the ninth embodiment corresponding to FIG. 12B also eliminates the dummy space 300, the dummy active regions 215 and 218, and the gate structure 239 of the original IC layout 200A. The ninth embodiment of FIG. 12B also reduces the sizes of the dielectric isolation structures (such as the electrical isolation structure 250) and the active regions (such as the active regions 210 and 216). However, whereas the eighth embodiment of FIG. 11B implements a continuous dielectric isolation structure 231 in the edge region 120B of the revised IC layout 200B, the ninth embodiment of FIG. 12B implements a plurality of dielectric isolation structures, such as the dielectric isolation structures 311 and 312, similar to the fifth embodiment shown in FIG. 8B. As such, the ninth embodiment may be viewed as a combination of the eighth embodiment of FIG. 11B and the fifth embodiment of FIG. 8B. As discussed above, the dielectric isolation structure 311 and the 312 are each configured to have the length L1, where L1 >=2×D1+2×S1, 0.5<D1/G1<10, 1<S1/G1<10, and 1<L1/G1<40. These value ranges allow the dielectric isolation structures 311 and 312 to sufficiently prevent or mitigate the potential epi mushroom issues discussed above. In any case, the ninth embodiment of FIG. 12B also achieves 7 CPP or 3.5 SRM for the reduced size 291 of the edge region 120B in the revised IC layout 200B, which is a reduction of 3 CPP (or 1.5 SRM) compared to the original IC layout 200A.

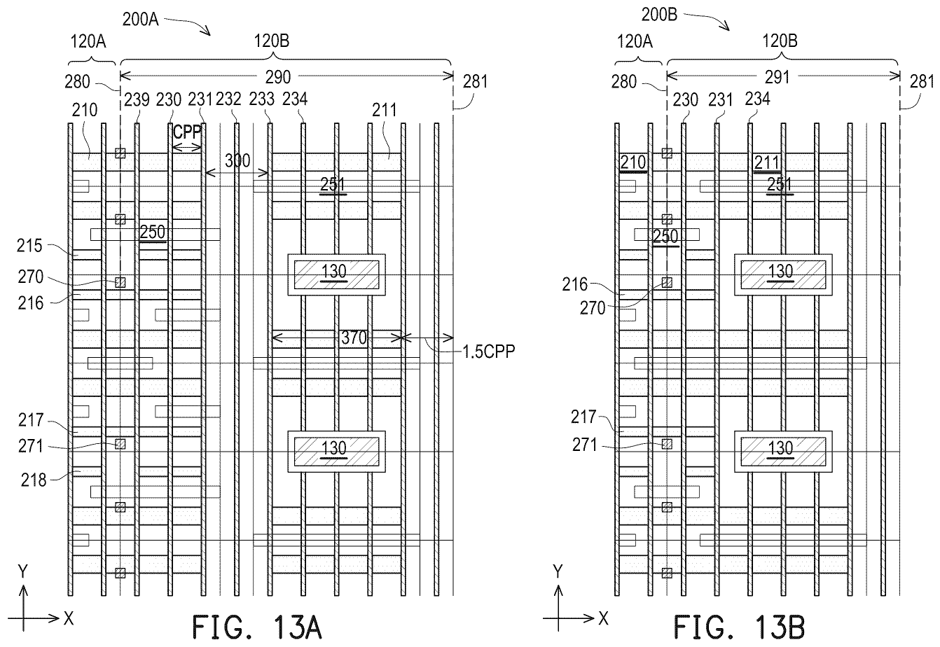

Referring now to FIGS. 13A-13B, a tenth embodiment of shrinking the edge region 120B of a memory device is illustrated. For reasons of consistency and clarity, similar components appearing in the figures discussed above will be labeled the same in FIGS. 13A-13B. In more detail, FIG. 13A illustrates an original IC layout 200A of a portion of the memory device 120 before the edge region 120B is shrunk, and FIG. 13B illustrates a revised IC layout 200B of the portion of the memory device 120 after the edge region 120B has been shrunk.

Similar to the eighth embodiment of FIG. 11B, the tenth embodiment corresponding to FIG. 13B also eliminates the dummy space 300, the dummy active regions 215 and 218, and the gate structure 239 of the original IC layout 200A. The tenth embodiment of FIG. 13B also reduces the sizes of the dielectric isolation structures (such as the electrical isolation structure 250) and the active regions (such as the active regions 210 and 216). However, whereas the eighth embodiments of FIG. 11B implements the dielectric isolation structure 310 in the edge region 120B of the revised IC layout 200B, the tenth embodiment of FIG. 13B implements no such dielectric isolation structure. Rather, the gate structure 231 is implemented in place of what would have been the dielectric isolation structure 310, as was the case for the third embodiment of FIG. 6B. It is understood that the tenth embodiment of FIG. 13B may be viewed as a combination of the eighth embodiment of FIG. 11B and the third embodiment of FIG. 6B. The tenth embodiment of FIG. 13B may be used in situations when the epi mushroom concerns are not significant enough to warrant the implementation of the dielectric isolation structure 310, which also helps to simply fabrication processes. In any case, the tenth embodiment of FIG. 13B also achieves 7 CPP or 3.5 SRM for the reduced size 291 of the edge region 120B in the revised IC layout 200B, which is a reduction of 3 CPP (or 1.5 SRM) compared to the original IC layout 200A.

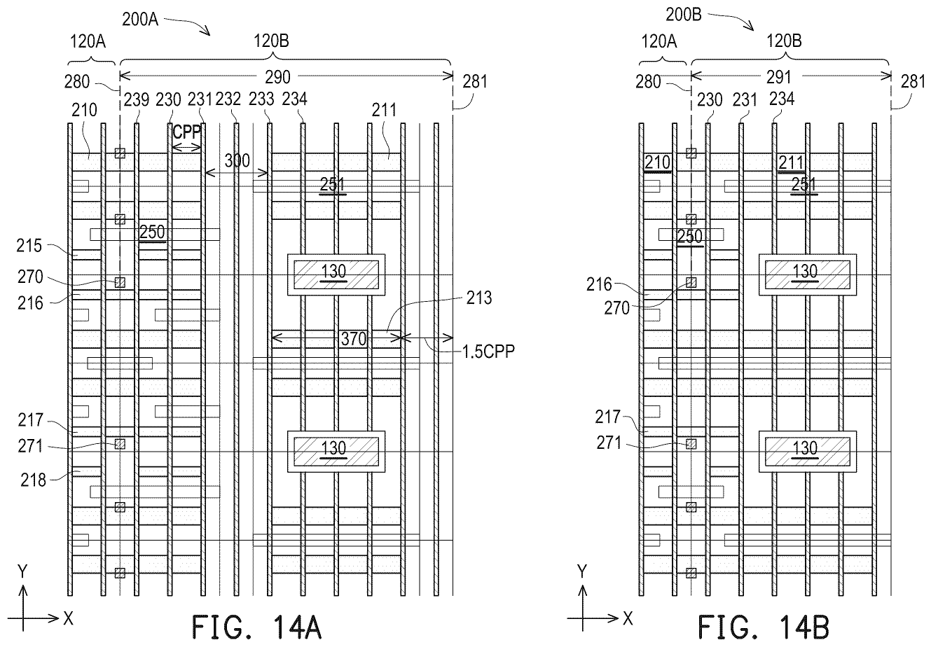

Referring now to FIGS. 14A-14B, an eleventh embodiment of shrinking the edge region 120B of a memory device is illustrated. For reasons of consistency and clarity, similar components appearing in the figures discussed above will be labeled the same in FIGS. 14A-14B. In more detail, FIG. 14A illustrates an original IC layout 200A of a portion of the memory device 120 before the edge region 120B is shrunk, and FIG. 14B illustrates a revised IC layout 200B of the portion of the memory device 120 after the edge region 120B has been shrunk.

Similar to the tenth embodiment of FIG. 13B, the eleventh embodiment corresponding to FIG. 14B also eliminates the dummy space 300, the dummy active regions 215 and 218, and the gate structure 239 of the original IC layout 200A. The eleventh embodiment of FIG. 14B also reduces the sizes of the dielectric isolation structures (such as the electrical isolation structure 250) and the active regions (such as the active regions 210 and 216). Furthermore, the eleventh embodiment of FIG. 14B does not implement the dielectric isolation structure 310 in the edge region 120B of the revised IC layout 200B either, but rather, the gate structure 231 is implemented in place of what would have bene the dielectric isolation structure 310, as is the case for the tenth embodiment.

Compared to the tenth embodiment, however, the eleventh embodiment further shrinks the active regions 211 and 213 in the X-direction. For example, whereas the active region 213 (or 211) has the horizontal dimension 370 in the original IC layout 200A of FIG. 5A, the active region 213 (or 211) has horizontal dimension 371 in the revised IC layout 200B of FIG. 5B. The horizontal dimension 371 is less than the horizontal dimension 370, for example, by 1 CPP, similar to the second embodiment discussed above with reference to FIG. 5B. It is understood that the eleventh embodiment of FIG. 14B may be viewed as a combination of the tenth embodiment of FIG. 14B and the second embodiment of FIG. 5B. In any case, the eleventh embodiment of FIG. 14B achieves 6 CPP or 3 SRM for the reduced size 291 of the edge region 120B in the revised IC layout 200B, which is a reduction of 4 CPP (or 2 SRM) compared to the original IC layout 200A.

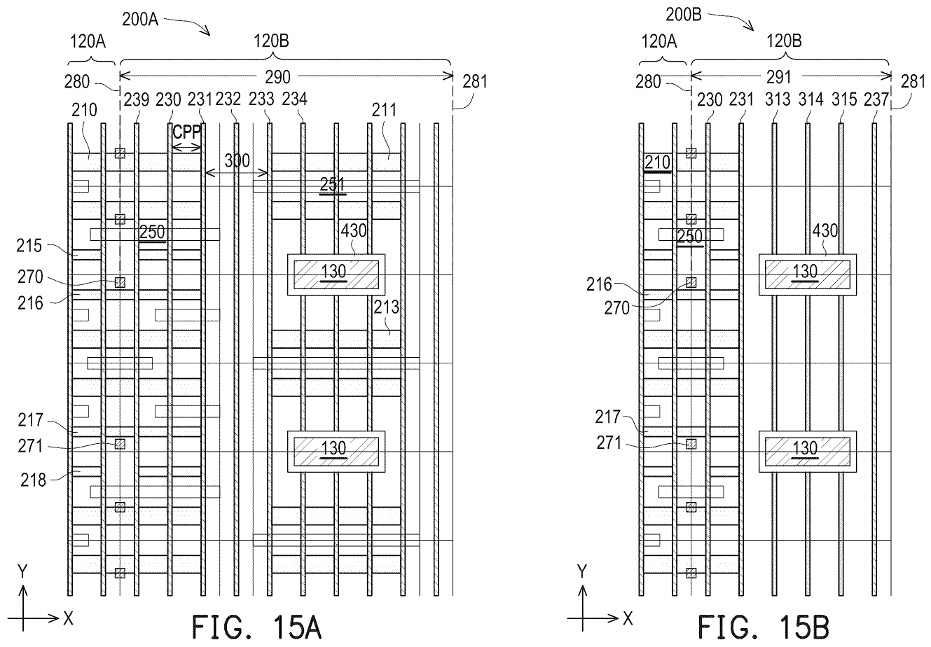

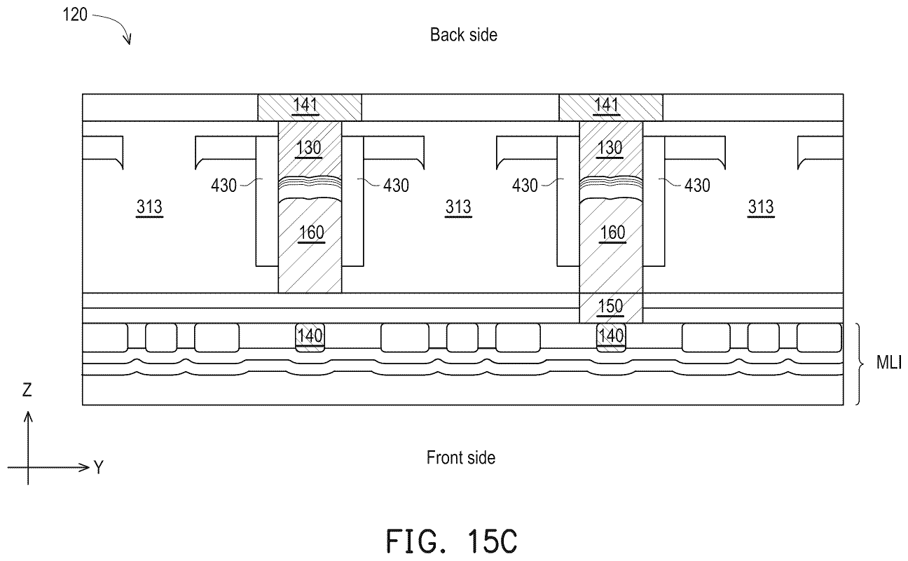

Referring now to FIGS. 15A-15B, a twelfth embodiment of shrinking the edge region 120B of a memory device is illustrated. For reasons of consistency and clarity, similar components appearing in the figures discussed above will be labeled the same in FIGS. 15A-15B. In more detail, FIG. 15A illustrates an original IC layout 200A of a portion of the memory device 120 before the edge region 120B is shrunk, and FIG. 15B illustrates a revised IC layout 200B of the portion of the memory device 120 after the edge region 120B has been shrunk.

Similar to various embodiments discussed above, the twelfth embodiment corresponding to FIG. 15B also eliminates the dummy space 300, the dummy active regions 215 and 218, and the gate structure 239 of the original IC layout 200A. The eleventh embodiment of FIG. 14B also reduces the sizes of the electrical isolation structures (such as the electrical isolation structure 250) and the active regions (such as the active regions 210 and 216). However, whereas the embodiments discussed above still implement various active regions (even if they are shrunk) in portions of the edge region 120B above or below the FTVs 130, the twelfth embodiment of FIG. 15B removes these active regions altogether in the revised IC layout 200B. The only portions of the active regions in the revised IC layout 200B are the portions of the active regions extending from the SRAM region 120A into the edge region 120B, such as portions of the active regions 210, 216, 217, etc.

The revised IC layout 200B also removes the electrical isolation structures in the edge region 120B, such as the electrical isolation structure 251. Instead, rather than using the electrical isolation structure 251 and other similar electrical isolation structures to provide electrical isolation between the FTVs 130, the revised IC layout 200B implements a plurality of dielectric isolation structures 313, 314, and 315 in the edge region 120B in order to provide the electrical isolation between the FTVs 130. The dielectric isolation structures 313-315 are similar to the dielectric isolation structure 310 discussed above, though they overlap with the FTVs 130 in the top view of FIG. 15B. In any case, it can be seen that the twelfth embodiment of FIG. 15B achieves 6 CPP or 3 SRM for the reduced size 291 of the edge region 120B in the revised IC layout 200B, which is a reduction of 4 CPP (or 2 SRM) compared to the original IC layout 200A.

To provide additional details of the dielectric isolation structures 313-315, FIG. 15C is a diagrammatic fragmentary cross-sectional side view of a portion of the memory device 120 fabricated according to the revised IC layout 200B. FIG. 15C is taken at a cross-sectional plane defined by the Y-direction horizontally and by the Z-direction vertically. As such, FIG. 15C may be referred to as a Y-cut view. Again, FIG. 15C has a front side (bottom side in FIG. 15C) and a back side (top side in FIG. 15C). Metallization structures may be implemented in both the front side and the back side of the memory device 120 to provide electrical connectivity. For example, the metal layer 140 (e.g., as a metal-0 layer of a multilayer interconnect structure (MLI)) may be formed over the front side of the memory device 120 to provide electrical connectivity to the components of the memory device 120 from the front side, and the metal layer 141 (e.g., as a back side metal-0 layer) may be formed over the back side of the memory device 120 to provide electrical connectivity to the components of the memory device 120 from the back side. The metal layer 140 and the metal layer 141 are electrically coupled together by a plurality of other conductive components, such as the conductive via 150, the conductive contact 160, as well as the FTV 130.

As shown in FIG. 15C, one of the dielectric isolation structures 313 is disposed between the FTVs 130 in the Y-direction. The other ones of the dielectric isolation structures 314 and 315 are implemented in a similar manner, and collectively, the dielectric isolation structures 313-315 provide electrical isolation between the FTVs 130 (as well as between the conductive contacts 160). Note that the FTVs 130 are also each surrounded by an electrical isolation structure 430 (also visible in the top view of FIG. 15B). The electrical isolation structure 430 may be formed at the same time, or using the same fabrication processes, as the electrical isolation structure 250. Here, the electrical isolation structure 430 provide further electrical isolation for the FTV 130 that it surrounds.

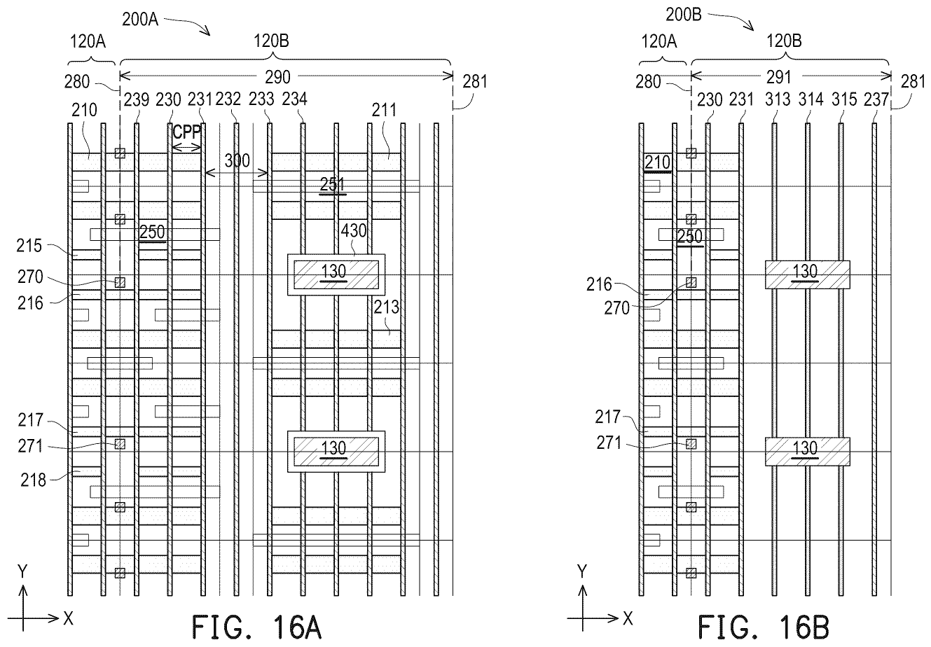

Referring now to FIGS. 16A-16B, a thirteenth embodiment of shrinking the edge region 120B of a memory device is illustrated. For reasons of consistency and clarity, similar components appearing in the figures discussed above will be labeled the same in FIGS. 16A-16B. In more detail, FIG. 16A illustrates an original IC layout 200A of a portion of the memory device 120 before the edge region 120B is shrunk, and FIG. 16B illustrates a revised IC layout 200B of the portion of the memory device 120 after the edge region 120B has been shrunk.

Similar to the twelfth embodiment discussed above, the thirteenth embodiment corresponding to FIG. 16B also eliminates the dummy space 300, the dummy active regions 215 and 218, the gate structure 239 of the original IC layout 200A, and the active regions around the FTVs 130 in the edge region 120B. The thirteenth embodiment of FIG. 16B also replaces the electrical isolation structures such as the electrical isolation structure 251 in the edge region 120B with dielectric isolation structures 313-315, as is the case for the twelfth embodiment of FIG. 15B. Unlike the twelfth embodiment, however, the thirteenth embodiment of FIG. 16B also removes the electrical isolation structure 430 that would have otherwise surrounded each of the FTVs 130 in the top view in the revised IC layout 200B. In any case, the thirteenth embodiment of FIG. 16B also achieves 6 CPP or 3 SRM for the reduced size 291 of the edge region 120B in the revised IC layout 200B, which is a reduction of 4 CPP (or 2 SRM) compared to the original IC layout 200A.

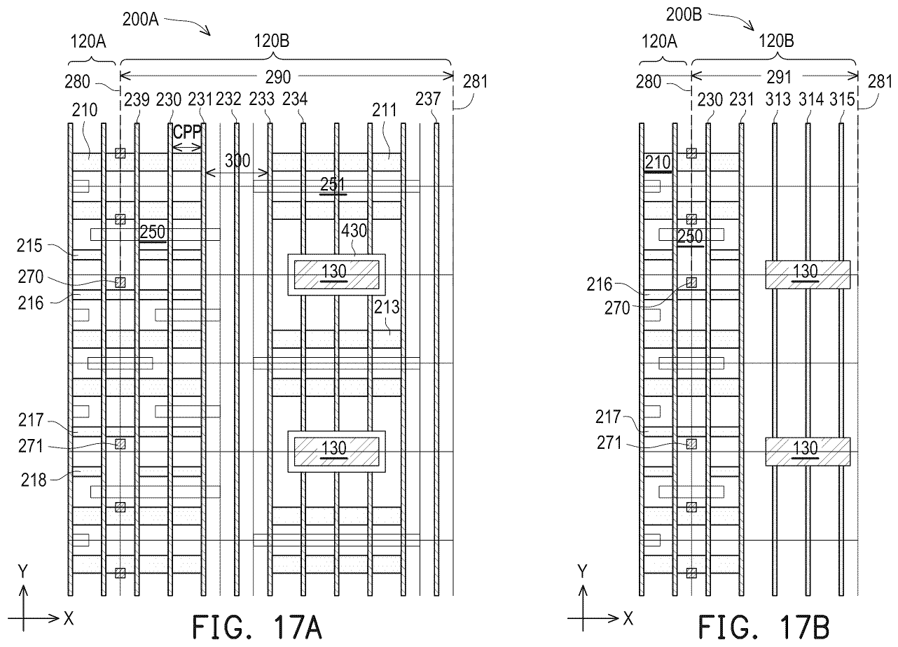

Referring now to FIGS. 17A-17B, a fourteenth embodiment of shrinking the edge region 120B of a memory device is illustrated. For reasons of consistency and clarity, similar components appearing in the figures discussed above will be labeled the same in FIGS. 17A-17B. In more detail, FIG. 17A illustrates an original IC layout 200A of a portion of the memory device 120 before the edge region 120B is shrunk, and FIG. 17B illustrates a revised IC layout 200B of the portion of the memory device 120 after the edge region 120B has been shrunk.

Similar to the thirteenth embodiment discussed above, the fourteenth embodiment corresponding to FIG. 17B also eliminates the dummy space 300, the dummy active regions 215 and 218, the gate structure 239 of the original IC layout 200A, and the active regions and the electrical isolation structures around the FTVs 130 in the edge region 120B. The fourteenth embodiment also implements the dielectric isolation structures 313-315 in the edge region 120B to provide electrical isolation for the FTVs 130. In addition, the fourteenth embodiment of FIG. 17B further shrinks the edge region 120B in the revised IC layout 200B, for example, by removing the gate structure 237 in the edge region 120B and moving the border 281 closer to the FTVs 130 accordingly. Due to the removal of the gate structure 237, the fourteenth embodiment of FIG. 17B achieves 5 CPP or 2.5 SRM for the reduced size 291 of the edge region 120B in the revised IC layout 200B, which is a reduction of 5 CPP (or 2.5 SRM) compared to the original IC layout 200A.

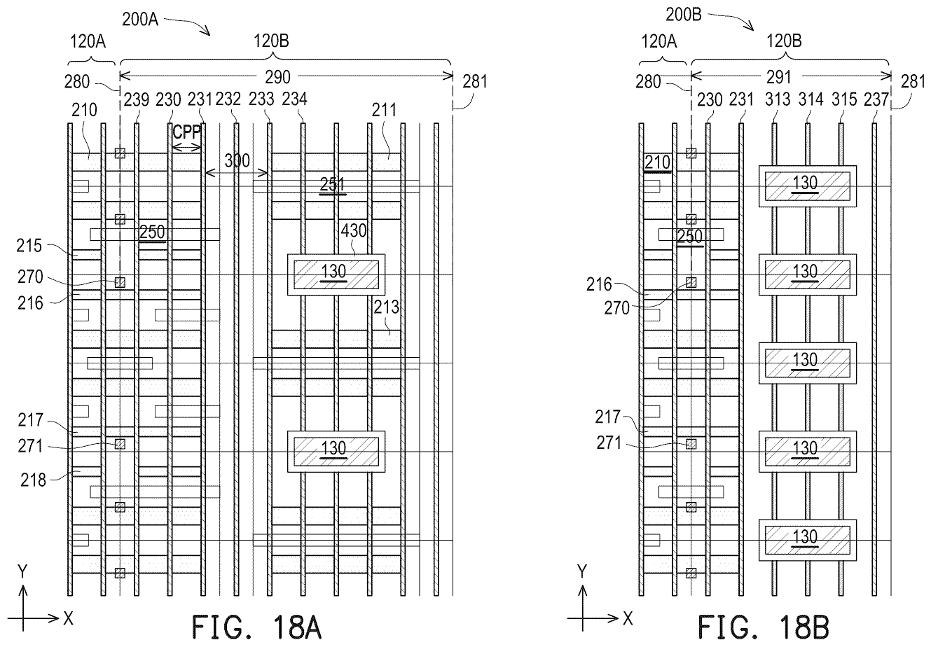

Referring now to FIGS. 18A-18B, a fifteenth embodiment of shrinking the edge region 120B of a memory device is illustrated. For reasons of consistency and clarity, similar components appearing in the figures discussed above will be labeled the same in FIGS. 18A-18B. In more detail, FIG. 18A illustrates an original IC layout 200A of a portion of the memory device 120 before the edge region 120B is shrunk, and FIG. 18B illustrates a revised IC layout 200B of the portion of the memory device 120 after the edge region 120B has been shrunk.

Similar to the twelfth embodiment discussed above with reference to FIG. 15B, the fifteenth embodiment corresponding to FIG. 18B also eliminates the dummy space 300, the dummy active regions 215 and 218, the gate structure 239 of the original IC layout 200A, and the active regions around the FTVs 130 in the edge region 120B. The fifteenth embodiment also implements the dielectric isolation structures 313-315 in the edge region 120B to provide electrical isolation for the FTVs 130. However, whereas the twelfth embodiment of FIG. 15B implements two FTVs 130 in the portion of the edge region 120B that is illustrated, the fifteenth embodiment of FIG. 18B implements five FTVs 130 in the same portion of the edge region 120B. The increase in the number of the FTVs 130 is made possible because the dielectric isolation structures 313-315 can provide a more effective electrical isolation between the FTVs 130 than the electrical isolation structures 251. In other words, the dielectric isolation structures 313-315 allow more FTVs 130 to be packed closer together (in the Y-direction) without risking electrical leakage between them. The increase in the number of FTVs is also advantageous, since each of the Vss or Vdd lines of the SRAM cells can be electrically tied to a dedicated one of the FTVs 130, rather than having to share a same FTV 130 between multiple Vss or Vdd lines. In any case, the fifteenth embodiment of FIG. 18B also achieves 6 CPP or 3 SRM for the reduced size 291 of the edge region 120B in the revised IC layout 200B, which is a reduction of 4 CPP (or 2 SRM) compared to the original IC layout 200A.

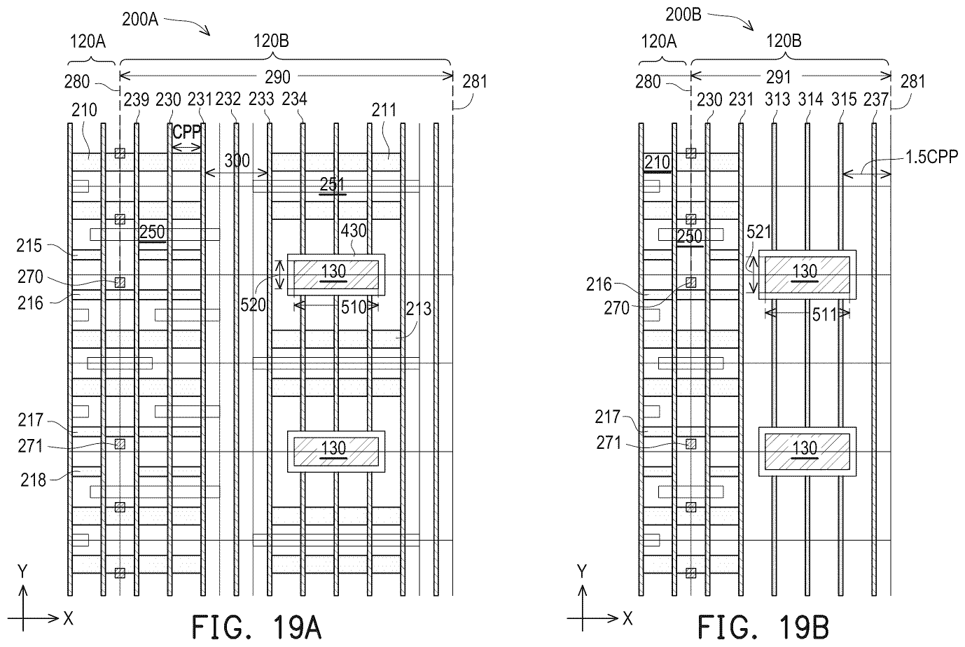

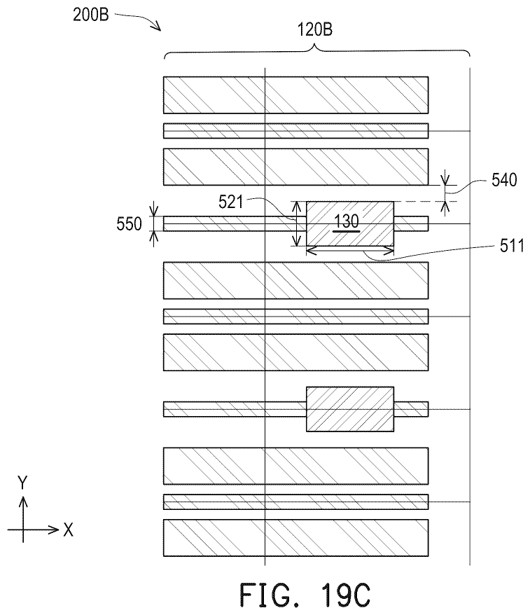

Referring now to FIGS. 19A-19B, a sixteenth embodiment of shrinking the edge region 120B of a memory device is illustrated. For reasons of consistency and clarity, similar components appearing in the figures discussed above will be labeled the same in FIGS. 19A-19B. In more detail, FIG. 19A illustrates an original IC layout 200A of a portion of the memory device 120 before the edge region 120B is shrunk, and FIG. 19B illustrates a revised IC layout 200B of the portion of the memory device 120 after the edge region 120B has been shrunk.

Similar to the twelfth embodiment discussed above with reference to FIG. 15B, the sixteenth embodiment corresponding to FIG. 18B also eliminates the dummy space 300, the dummy active regions 215 and 218, the gate structure 239 of the original IC layout 200A, and the active regions around the FTVs 130 in the edge region 120B. The sixteenth embodiment also implements the dielectric isolation structures 313-315 in the edge region 120B to provide electrical isolation for the FTVs 130. However, whereas the twelfth embodiment of FIG. 15B keeps the size of the FTVs 130 substantially the same in the revised IC layout 200B, the sixteenth embodiment of FIG. 19B enlarges the FTVs 130 in at least the Y-direction in the revised IC layout 200B. For example, in the original IC layout 200A, each of the FTVs 130 may have a dimension 510 measured in the X-direction, as well as a dimension 520 measured in the Y-direction. In the revised IC layout 200B, each of the FTVs 130 may be enlarged to have a dimension 521 that is greater than the dimension 520 in the Y-direction. The FTVs 130 may also have a dimension 511 in the X-direction, where the dimension 511 may be larger than, equal to, or smaller than the dimension 510 in the original IC layout 200A.

In any case, the enlargement of the FTVs 130 (e.g., enlarged in at least the Y-direction) helps to reduce a resistance of the FTVs 130, which improves device performance. The enlargement of the FTVs 130 is also made possible due to the removal of the active regions and electrical isolation structures 251 between the FTVs 130 and the implementation of the dielectric isolation structures 313-315, which provide sufficient electrical isolation even for the enlarged FTVs 130 (which are now closer to one another).

FIG. 19C is a portion of the revised IC layout 200B corresponding to the edge region 120B, but also with metal routing components included. For example, the FTV 130 is located between two adjacent bit-line (BL) metal lines. A distance 540 separates the FTV 130 from the nearest edge of the BL metal line. The distance 540 is greater than 0 to reduce the risk of electrical shorting between the FTV 130 and the nearest BL metal line. The FTV 130 is also located on, or overlaps with, a Vdd metal line. The Vdd metal line has a dimension 550 measured in the Y-direction. In some embodiments, the values of the dimension 521 and the dimension 550 are configured such that a ratio between the dimension 521 and the dimension 550 is greater than about 0.5 but less than about 10. Such a ratio range is not randomly configured but specifically chosen to ensure that the FTV 130 is resized to be large enough to achieve a suitable resistance reduction, while not too large to risk electrical shorting with adjacent metal lines such as the BL metal lines.

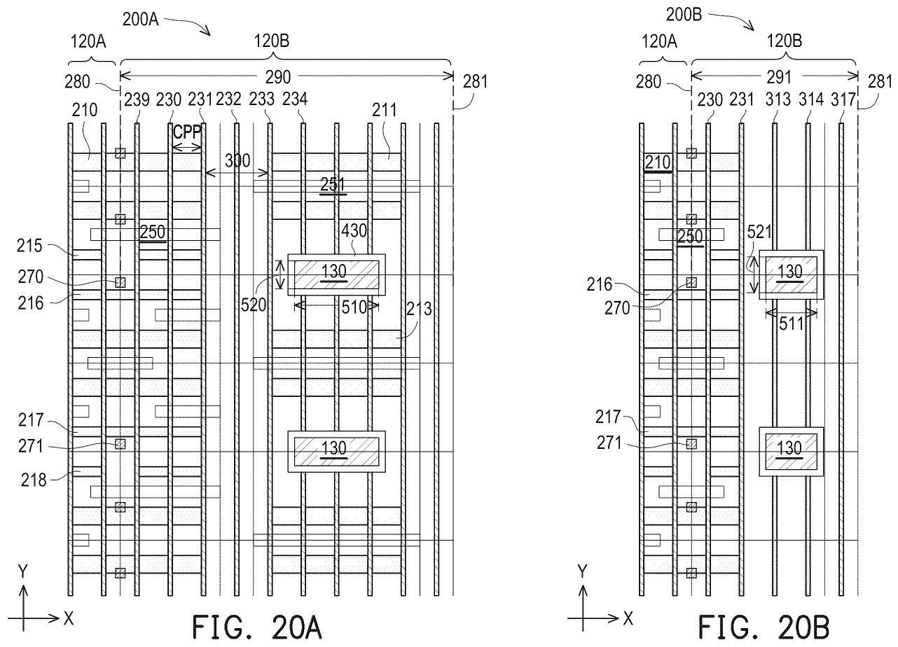

In any case, as shown in FIG. 19B, the sixteenth embodiment achieves 6 CPP or 3 SRM for the reduced size 291 of the edge region 120B in the revised IC layout 200B, which is a reduction of 4 CPP (or 2 SRM) compared to the original IC layout 200A. However, further size reduction of the edge region 120B also possible. This is illustrated in FIGS. 20A-20B, which correspond to a seventeenth embodiment of shrinking the edge region 120B of a memory device is illustrated. For reasons of consistency and clarity, similar components appearing in the figures discussed above will be labeled the same in FIGS. 20A-20B. In more detail, FIG. 20A illustrates an original IC layout 200A of a portion of the memory device 120 before the edge region 120B is shrunk, and FIG. 20B illustrates a revised IC layout 200B of the portion of the memory device 120 after the edge region 120B has been shrunk.

Similar to the sixteenth embodiment discussed above with reference to FIG. 19B, the seventeenth embodiment corresponding to FIG. 20B also eliminates the dummy space 300, the dummy active regions 215 and 218, the gate structure 239 of the original IC layout 200A, and the active regions around the FTVs 130 in the edge region 120B. The seventeenth embodiment also resizes the FTVs 130. However, whereas the FTVs 130 may or may not be resized in the X-direction in the sixteenth embodiment of FIG. 19B, the FTVs 130 are resized to achieve a smaller dimension 511 in the seventeenth embodiment of FIG. 20B. That is, the dimension 511 in the revised IC layout 200B is smaller than the dimension 510 in the original IC layout 200A. In some embodiments, the dimension 511 of the FTVs 130 may be shrunk sufficiently such that only two dielectric isolation structures 313-314 (as opposed to three dielectric isolation structures 313-315) overlap with the FTVs 130 in the top view. In other words, the dielectric isolation structure 315 need not be implemented in the revised IC layout 200B in the seventeenth embodiment of FIG. 20B. This allows the edge region 120B to be further shrunk in the X-direction, as the seventeenth embodiment achieves 5 CPP or 2.5 SRM for the reduced size 291 of the edge region 120B in the revised IC layout 200B, which is a reduction of 5 CPP (or 2.5 SRM) compared to the original IC layout 200A.

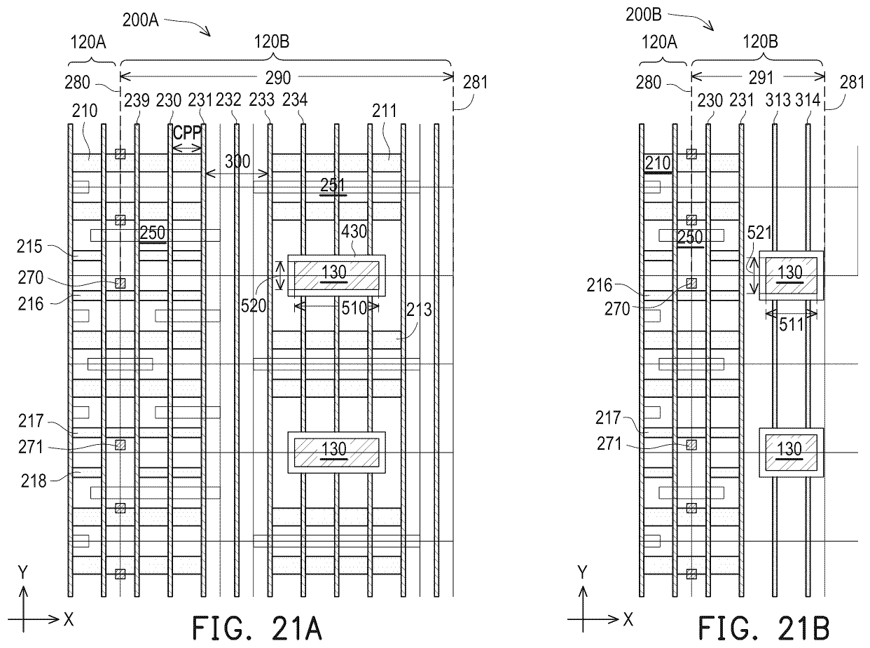

Referring now to FIGS. 21A-21B, an eighteenth embodiment of shrinking the edge region 120B of a memory device is illustrated. For reasons of consistency and clarity, similar components appearing in the figures discussed above will be labeled the same in FIGS. 21A-21B. In more detail, FIG. 21A illustrates an original IC layout 200A of a portion of the memory device 120 before the edge region 120B is shrunk, and FIG. 21B illustrates a revised IC layout 200B of the portion of the memory device 120 after the edge region 120B has been shrunk.

Similar to the seventeenth embodiment discussed above with reference to FIG. 20B, the seventeenth embodiment corresponding to FIG. 21B also eliminates the dummy space 300, the dummy active regions 215 and 218, the gate structure 239 of the original IC layout 200A, and the active regions around the FTVs 130 in the edge region 120B. The eighteenth embodiment also resizes the FTVs 130 in both the X-direction and the Y-direction and implements the dielectric isolation structures 313-314 in the edge region 120B to provide electrical isolation for the FTVs 130. However, whereas the seventeenth embodiment of FIG. 20B still implements a gate structure 317 between the FTVs 130 and the imaginary line 281 (which represents the border of the edge region 120B), the eighteenth embodiment of FIG. 21B eliminates the gate structure 317 from the revised IC layout 200B as well. In this manner, the size of the edge region 120B is further shrunk in the X-direction, as the eighteenth embodiment achieves 4 CPP or 2 SRM for the reduced size 291 of the edge region 120B in the revised IC layout 200B, which is a reduction of 6 CPP (or 3 SRM) compared to the original IC layout 200A.

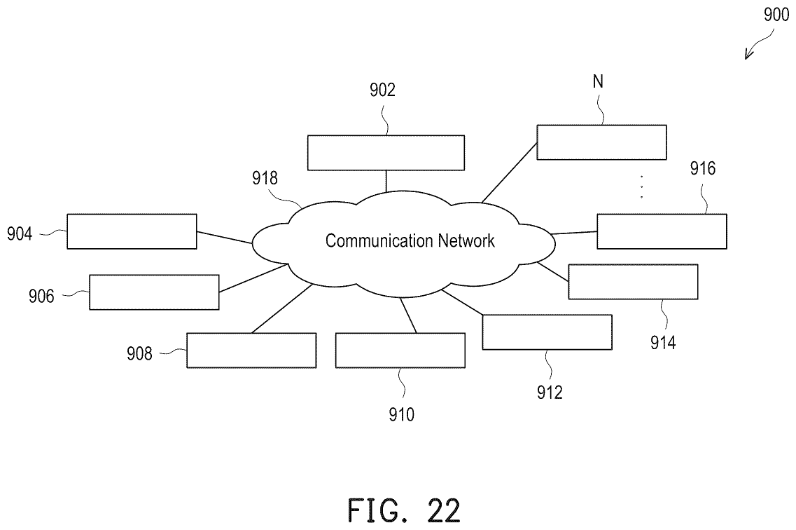

FIG. 22 illustrates an integrated circuit fabrication system 900 according to embodiments of the present disclosure. The fabrication system 900 includes a plurality of entities 902, 904, 906, 908, 910, 912, 914, 916 . . . , N that are connected by a communications network 918. The network 918 may be a single network or may be a variety of different networks, such as an intranet and the Internet, and may include both wire line and wireless communication channels.

In an embodiment, the entity 902 represents a service system for manufacturing collaboration; the entity 904 represents a user, such as product engineer monitoring the interested products; the entity 906 represents an engineer, such as a processing engineer to control process and the relevant recipes, or an equipment engineer to monitor or tune the conditions and setting of the processing tools; the entity 908 represents a metrology tool for IC testing and measurement; the entity 910 represents a semiconductor processing tool, such an EUV tool that is used to perform lithography processes to define the components of an SRAM device; the entity 912 represents a virtual metrology module associated with the processing tool 910; the entity 914 represents an advanced processing control module associated with the processing tool 910 and additionally other processing tools; and the entity 916 represents a sampling module associated with the processing tool 910.

Each entity may interact with other entities and may provide integrated circuit fabrication, processing control, and/or calculating capability to and/or receive such capabilities from the other entities. Each entity may also include one or more computer systems for performing calculations and carrying out automations. For example, the advanced processing control module of the entity 914 may include a plurality of computer hardware having software instructions encoded therein. The computer hardware may include hard drives, flash drives, CD-ROMs, RAM memory, display devices (e.g., monitors), input/output device (e.g., mouse and keyboard). The software instructions may be written in any suitable programming language and may be designed to carry out specific tasks.

The integrated circuit fabrication system 900 enables interaction among the entities for the purpose of integrated circuit (IC) manufacturing, as well as the advanced processing control of the IC manufacturing. In an embodiment, the advanced processing control includes adjusting the processing conditions, settings, and/or recipes of one processing tool applicable to the relevant wafers according to the metrology results.

In another embodiment, the metrology results are measured from a subset of processed wafers according to an optimal sampling rate determined based on the process quality and/or product quality. In yet another embodiment, the metrology results are measured from chosen fields and points of the subset of processed wafers according to an optimal sampling field/point determined based on various characteristics of the process quality and/or product quality.

One of the capabilities provided by the IC fabrication system 900 may enable collaboration and information access in such areas as design, engineering, and processing, metrology, and advanced processing control. Another capability provided by the IC fabrication system 900 may integrate systems between facilities, such as between the metrology tool and the processing tool. Such integration enables facilities to coordinate their activities. For example, integrating the metrology tool and the processing tool may enable manufacturing information to be incorporated more efficiently into the fabrication process or the APC module, and may enable wafer data from the online or in site measurement with the metrology tool integrated in the associated processing tool.

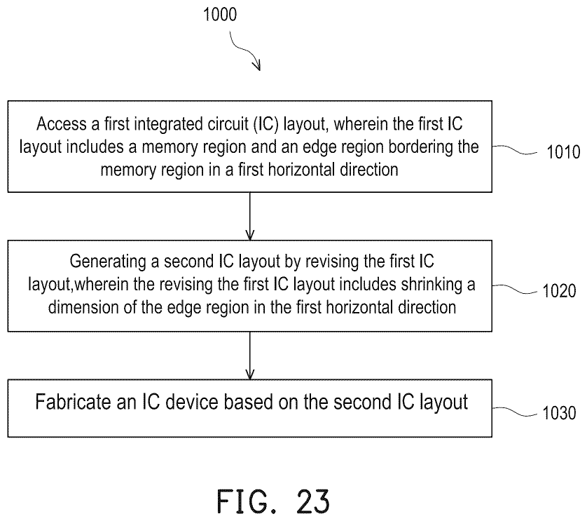

FIG. 23 is a flowchart illustrating a method 1000 of revising an IC layout design according to embodiments of the present disclosure. The method 1000 includes a step 1010 to access a first integrated circuit (IC) layout. The first IC layout includes a memory region and an edge region bordering the memory region in a first horizontal direction.

The method 1000 includes a step 1020 to generate a second IC layout by revising the first IC layout. The revising the first IC layout includes shrinking a dimension of the edge region in the first horizontal direction.

The method 1000 includes a step 1030 to fabricate an IC device according to the second IC layout.

In some embodiments, the edge region in the first IC layout contains a plurality of active regions and a dummy space. No portion of the active regions extend into the dummy space. In some embodiments, the revising the first IC layout is performed at least in part by removing the dummy space in the second IC layout.

In some embodiments, the revising the first IC layout is performed by replacing the dummy space with a dielectric isolation structure or with a gate structure in the second IC layout. The dielectric isolation structure or the gate structure extend in a second horizontal direction perpendicular to the first horizontal direction.

In some embodiments, in the second IC layout: a first active region of the active regions is located immediately adjacent to a first side of the dielectric isolation structure, and a second active region of the active regions is located immediately adjacent to a second side of the dielectric isolation structure opposite the first side. In some embodiments, the replacing the dummy space with the dielectric isolation structure comprises implementing a plurality of discrete dielectric segments as the dielectric isolation structure in the second IC layout. The discrete dielectric segments are separated from one another in the second horizontal direction. In some embodiments, the revising the first IC layout is performed at least in part by shrinking a subset of the active regions in the first horizontal direction in the second IC layout.

In some embodiments, according to the first IC layout, the edge region has a first border that borders the memory region and a second border that is opposite the first border. The edge region in the first IC layout contains a plurality of feedthrough vias (FTVs) that are spaced apart from one another in a second horizontal direction perpendicular to the first horizontal direction. In some embodiments, the revising the first IC layout is performed at least in part by shrinking a portion of the edge region between the second border and the plurality of FTVs in the second IC layout.

In some embodiments, the revising the first IC layout is performed at least in part by increasing a number of the FTVs in the second IC layout. In some embodiments, the revising the first IC layout is performed at least in part by enlarging each of the FTVs in the second horizontal direction in the second IC layout or by shrinking each of the FTVs in the first horizontal direction in the second IC layout.

It is understood that the method 1000 may include further steps performed before, during, or after the steps 1010-1030. For example, the method 1000 may include forming gate structures, forming source/drain regions, forming interlayer dielectric (ILD), forming an interconnect structure, etc. For reasons of simplicity, these additional steps are not discussed herein in detail.

The advanced lithography process, method, and materials described above can be used in many applications, including fin-type field effect transistors (FinFETs). For example, the fins may be patterned to produce a relatively close spacing between features, for which the above disclosure is well suited. In addition, spacers used in forming fins of FinFETs, also referred to as mandrels, can be processed according to the above disclosure. It is also understood that the various aspects of the present disclosure discussed above may apply to multi-channel devices such as Gate-All-Around (GAA) devices. To the extent that the present disclosure refers to a fin structure or FinFET devices, such discussions may apply equally to the GAA devices.

In summary, the present disclosure pertains to revising an IC layout of a memory device by shrinking an edge region of the memory device. The shrinking of the edge region may be achieved in a variety ways. In some embodiments, the shrinking of the edge region may be performed by removing a dummy space in the edge region, where a dielectric isolation structure may be implemented in place of the dummy space to provide electrical isolation. The dummy structure may also be implemented as a plurality of discrete segments. In some embodiments, the shrinking of the edge region may be achieved by resizing or removing a subset of the active regions in the edge region. In some embodiments, the shrinking of the edge region may include implementing a plurality of dielectric isolation structures between the FTVs in the edge region. The implementation of the dielectric isolation structures allow the FTVs to be resized as well, which could allow the border of the edge region to be moved closer to the FTVs. A greater number of the FTVs may also be implemented, since the dielectric isolation structures between the FTVs can reduce potential electrical leakage between the FTVs more effectively.

By shrinking the edge region, the present disclosure may offer advantages over conventional devices. However, it is understood that not all advantages are discussed herein, different embodiments may offer different advantages, and that no particular advantage is required for any embodiment. One advantage is a more efficient utilization of chip real estate. For example, by shrinking the edge region, the memory cell region of the device may be enlarged to pack more memory cells (e.g., SRAM cells) therein, assuming the overall IC chip size remains the same. Alternatively, if the size of the memory cell region remains the same, the overall IC chip size may be reduced by the shrinking of the edge region. Another advantage is associated with the increase in the number of the FTVs, as this allows the signal lines (e.g., Vdd or Vss) to each have their own dedicated FTVs. Yet another advantage is associated with the enlargement of the FTVs, as that could lead to a lower electrical resistance of the FTVs, which may help improve device performance such as device speed. Other advantages may include compatibility with existing fabrication processes and ease of implementation.

In one example aspect, the present disclosure provides a device. The device includes a memory region. The memory region includes a plurality of memory cells. Each of the memory cells has a first dimension in a first horizontal direction. The device include an edge region bordering the memory region in the first horizontal direction. The edge region has a second dimension in the first horizontal direction. The second dimension is less than or equal to about 4 times the first dimension.

Another aspect of the present disclosure pertains to an integrated circuit (IC) layout. The IC layout includes a memory region. The memory region includes a plurality of memory cells, and wherein each of the memory cells has a first dimension in a first horizontal direction. The IC layout includes an edge region bordering the memory region in a first horizontal direction. The edge region includes a dielectric isolation structure that extends in a second horizontal direction different from the first horizontal direction.

Yet another aspect of the present disclosure pertains to a method. The method includes accessing a first integrated circuit (IC) layout. The first IC layout includes a memory region and an edge region bordering the memory region in a first horizontal direction. The method includes generating a second IC layout by revising the first IC layout. The revising the first IC layout includes shrinking a dimension of the edge region in the first horizontal direction.

The foregoing has outlined features of several embodiments. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

What is claimed is:

1. A device, comprising:
a memory region, wherein the memory region includes a plurality of memory cells, and wherein each of the memory cells has a first dimension in a first horizontal direction; and
an edge region bordering the memory region in the first horizontal direction, wherein the edge region has a second dimension in the first horizontal direction, and wherein the second dimension is less than or equal to about 4 times the first dimension.

2. The device of claim 1, wherein the second dimension is equal to about 4 times the first dimension, about 3.5 times the first dimension, about 3 times the first dimension, about 2.5 times the first dimension, or about 2 times the first dimension.

3. The device of claim 1, wherein the edge region includes:
a plurality of feedthrough vias (FTVs) that are disposed relative to one another in a second horizontal direction perpendicular to the first horizontal direction; and
a dielectric isolation structure that extends in the second horizontal direction.

4. The device of claim 3, wherein:
the edge region further includes a first active region and a second active region that each extend in the first horizontal direction;
the first active region is directly abutted to a first side of the dielectric isolation structure; and
the second active region is directly abutted to a second side of the dielectric isolation structure.

5. The device of claim 3, wherein:
the edge region has a first border that borders the memory region and a second border opposite the first border;
the first border and the second border each extend in the second horizontal direction; and
a distance between the second border and one of the FTVs is less than the first dimension.

6. The device of claim 3, wherein:
the dielectric isolation structure includes a plurality of discrete segments that are spaced apart from one another in the second horizontal direction; and
each of the discrete segments is located between a respective one of the FTVs and a border between the memory region and the edge region.

7. The device of claim 3, wherein:
the dielectric isolation structure includes at least a first dielectric isolation structure, a second dielectric isolation structure, and a third dielectric isolation structure;
the first, second, and third dielectric isolation structures are spaced apart from one another in the first horizontal direction; and
the FTVs are located between each of the first, second, and third dielectric isolation structures in the second horizontal direction in a top view.

8. An integrated circuit (IC) layout, comprising:
a memory region, wherein the memory region includes a plurality of memory cells, and wherein each of the memory cells has a first dimension in a first horizontal direction; and
an edge region bordering the memory region in a first horizontal direction, wherein the edge region includes a dielectric isolation structure that extends in a second horizontal direction different from the first horizontal direction.

9. The IC layout of claim 8, wherein the dielectric isolation structure includes a plurality of discrete segments that are spaced apart from one another in the second horizontal direction.

10. The IC layout of claim 8, wherein:
the edge region includes at least a first feedthrough vias (FTV) and a second FTV;
the first FTV and the second FTV are spaced apart from one another in the second horizontal direction; and
portions of the dielectric isolation structure are disposed between the first FTV and the second FTV in the second horizontal direction.

11. A method, comprising:
accessing a first integrated circuit (IC) layout, wherein the first IC layout includes a memory region and an edge region bordering the memory region in a first horizontal direction; and
generating a second IC layout by revising the first IC layout, wherein the revising the first IC layout includes shrinking a dimension of the edge region in the first horizontal direction.

12. The method of claim 11, further comprising: fabricating an IC device according to the second IC layout.

13. The method of claim 11, wherein:
the edge region in the first IC layout contains a plurality of active regions and a dummy space;
no portion of the active regions extend into the dummy space; and
the revising the first IC layout is performed at least in part by removing the dummy space in the second IC layout.

14. The method of claim 13, wherein the revising the first IC layout is performed by replacing the dummy space with a dielectric isolation structure or with a gate structure in the second IC layout, the dielectric isolation structure or the gate structure extending in a second horizontal direction perpendicular to the first horizontal direction.

15. The method of claim 14, wherein in the second IC layout:
a first active region of the active regions is located immediately adjacent to a first side of the dielectric isolation structure; and
a second active region of the active regions is located immediately adjacent to a second side of the dielectric isolation structure opposite the first side.

16. The method of claim 14, wherein the replacing the dummy space with the dielectric isolation structure comprises implementing a plurality of discrete dielectric segments as the dielectric isolation structure in the second IC layout, wherein the discrete dielectric segments are separated from one another in the second horizontal direction.

17. The method of claim 13, wherein the revising the first IC layout is performed at least in part by shrinking a subset of the active regions in the first horizontal direction in the second IC layout.

18. The method of claim 11, wherein:
according to the first IC layout, the edge region has a first border that borders the memory region and a second border that is opposite the first border;
the edge region in the first IC layout contains a plurality of feedthrough vias (FTVs) that are spaced apart from one another in a second horizontal direction perpendicular to the first horizontal direction; and
the revising the first IC layout is performed at least in part by shrinking a portion of the edge region between the second border and the plurality of FTVs in the second IC layout.

19. The method of claim 18, wherein the revising the first IC layout is performed at least in part by increasing a number of the FTVs in the second IC layout.

20. The method of claim 18, wherein the revising the first IC layout is performed at least in part by enlarging each of the FTVs in the second horizontal direction in the second IC layout or by shrinking each of the FTVs in the first horizontal direction in the second IC layout.
